(19) United States
(12) Patent Application Publication
(10) Pub. No.: US 2026/0013346 A1
(43) Pub. Date: Jan. 8, 2026

(54) DISPLAY SUBSTRATE, MANUFACTURING METHOD THEREFOR, AND DISPLAY APPARATUS

(71) Applicants: Yunnan Invensight Optoelectronics Technology Co., Ltd., Kunming,Yunnan (CN); BOE Technology Group Co., Ltd., Beijing (CN); Beijing BOE Technology Development Co., Ltd., Beijing (CN)

(72) Inventors: Shanghong JIANG, Beijing (CN); Qingshan SHAN, Beijing (CN); Shengji YANG, Beijing (CN); Pengcheng LU, Beijing (CN); Xiao BAI, Beijing (CN); Longfei FAN, Beijing (CN); Dacheng ZHANG, Beijing (CN)

(21) Appl. No.: 18/881,746

(22) PCT Filed: Apr. 18, 2024
(86) PCT No.: PCT/CN2024/088542

§ 371 Date: Jan. 7, 2025

(30) Foreign Application Priority Data
May 11, 2023 (CN) 202310532736.2

(51) Int. Cl. H10K 59/131; H10K 59/12

(52) U.S. Cl. CPC H10K 59/131; H10K 59/1201

(57) ABSTRACT

A display substrate, a manufacturing method therefor, and a display apparatus. The display substrate comprises a plurality of sub-pixels; each sub-pixel comprises a pixel drive circuit; each pixel drive circuit at least comprises a first transistor, a second transistor, a third transistor and a fourth transistor; a first electrode of the first transistor is connected to a data signal line, and a second electrode of the first transistor is connected to a gate of a fourth transistor; a first electrode of the second transistor is connected to a first power line, and a second electrode of the second transistor is connected to a first electrode of the fourth transistor; a first electrode of each third transistor is connected to a second power line, and a second electrode of the third transistor is connected to a second electrode of the fourth transistor.

### CROSS-REFERENCE TO RELATED APPLICATIONS

The present application is a U.S. National Phase Entry of International Application No. PCT/CN2024/088542 having an international filing date of Apr. 18, 2024, which claims priority to Chinese Patent Application No. 202310532736.2 filed to the CNIPA on May 11, 2023 and entitled “Display Substrate and Manufacturing Method Therefor, and Display Apparatus”. The entire contents of the above-identified applications are incorporated herein by reference.

### TECHNICAL FIELD

The present disclosure relates to, but is not limited to, a field of display technology, and particularly to a display substrate and a manufacturing method therefor, and a display apparatus.

### BACKGROUND

Micro Organic Light Emitting Diodes (Micro OLEDs) are micro displays developed in recent years, and a silicon-based Organic Light Emitting Diode (OLED) is one of the Micro OLEDs. The silicon-based OLED can not only realize active addressing of pixels, but also can realize manufacturing of structures such as pixel drive circuits on a silicon-based base substrate, which is conducive to reduce system volume and realize lightweight. The Silicon-based OLEDs are manufactured using mature Complementary Metal Oxide Semiconductor (CMOS) integrated circuit process, have advantages such as small size, high Pixels Per Inch (PPI), and high refresh rate, and are widely used in a near-eye display field of Virtual Reality (VR) or Augmented Reality (AR).

### SUMMARY

The following is a summary of subject matters described herein in detail. The summary is not intended to limit the protection scope of claims.

In one aspect, the present disclosure provides a display substrate including a plurality of sub-pixels forming a plurality of pixel rows and a plurality of pixel columns, wherein at least one sub-pixel includes a pixel drive circuit, the pixel drive circuit at least includes a first transistor, a second transistor, a third transistor, and a fourth transistor; a first electrode of the first transistor is connected to a data signal line, a second electrode of the first transistor is connected to a gate electrode of the fourth transistor, a first electrode of the second transistor is connected to a first power supply line, a second electrode of the second transistor is connected to a first electrode of the fourth transistor, a first electrode of the third transistor is connected to a second power supply line, a second electrode of the third transistor is connected to a second electrode of the fourth transistor. In the at least one sub-pixel, along a direction of a pixel row, the sub-pixel has a pixel width, and there is an inter-electrode distance between the first electrode of the first transistor and the second electrode of the first transistor, and the inter-electrode distance is greater than or equal to 0.5*the pixel width.

In an exemplary implementation mode, the inter-electrode distance is greater than or equals to 0.85 μm.

In an exemplary implementation mode, along the direction of the pixel row, there is a first distance between the first electrode of the first transistor and the data signal line, and there is a second distance between the second electrode of the first transistor and the data signal line, and the second distance is greater than the first distance.

In an exemplary implementation mode, the second distance is greater than or equals to 5*the first distance.

In an exemplary implementation mode, in the at least one sub-pixel, the first transistor at least includes a first active layer being in a shape of a strip extending along the direction a pixel row, the first active layer includes at least a first region and a second region, the first region of the first active layer and the second region of the first active layer are arranged in sequence along the direction of the pixel row.

In an exemplary implementation mode, the at least one sub-pixel further includes a data connection electrode and an inter-electrode connection electrode; a first end of the data connection electrode is connected to the first region of the first active layer through a first via, a second end of the data connection electrode is connected to the data signal line; a first end of the inter-electrode connection electrode is connected to the second region of the first active layer through a second via, and a second end of the inter-electrode connection electrode is connected to the gate electrode of the fourth transistor; the inter-electrode distance between the first electrode of the first transistor and the second electrode of the first transistor is a distance between a geometric center of the first via and a geometric center of the second via, the first distance between the first electrode of the first transistor and the data signal line is a distance between the geometric center of the first via and an edge of the data signal line on a side close to the first transistor, and the second distance between the second electrode of the first transistor and the data signal line is a distance between the geometric center of the second via and the edge of the data signal line on the side close to the first transistor.

In an exemplary implementation mode, in the at least one sub-pixel, the second transistor includes at least a second active layer, the third transistor includes at least a third active layer, and the fourth transistor includes at least a fourth active layer, the second active layer, the third active layer, and the fourth active layer are connected to each other to form an integral structure.

In an exemplary implementation mode, in at least one pixel column, second active layers of two adjacent sub-pixels are connected to each other to form an integral structure.

In an exemplary implementation mode, in at least one pixel column, pixel drive circuits of two adjacent sub-pixels are mirror-symmetrical with respect to a pixel centerline, the pixel centerline is a straight line between two adjacent pixel rows and extending along a direction of a pixel row.

In an exemplary implementation mode, in the at least one sub-pixel, the pixel drive circuit further includes a first storage capacitor and a second storage capacitor, and wherein, the first storage capacitor includes a first electrode plate and a second electrode plate, an orthographic projection of the first electrode plate on a plane of the display substrate at least partially overlaps with an orthographic projection of the second electrode plate on the plane of the display substrate, the first electrode plate is connected to the gate electrode of the fourth transistor, and the second electrode plate is connected to the first electrode of the fourth transistor; the second storage capacitor includes a third electrode plate and a fourth electrode plate, an orthographic projection of the third electrode plate on the plane of the display substrate at least partially overlaps with an orthographic projection of the fourth electrode plate on the plane of the display substrate, the third electrode plate is connected to the first electrode of the fourth transistor, and the fourth electrode plate is connected to the first power supply line.

In an exemplary implementation mode, in the at least one sub-pixel, the orthographic projection of at least one of the first electrode plate, the second electrode plate, the third electrode plate, and the fourth electrode plate on the plane of the display substrate does not overlap with an orthographic projection of the data signal line on the plane of the display substrate.

In an exemplary implementation mode, in the at least one sub-pixel, an orthographic projection of the first power supply line on the plane of the display substrate does not overlap with the orthographic projection of the data signal line on the plane of the display substrate.

In an exemplary implementation mode, the at least one sub-pixel further includes at least one power supply connection line, the power supply connection line is in a shape of a line extending along a direction of a pixel row, the first power supply line is in a shape of a line extending along a direction of a pixel column, and the first power supply line and the power supply connection line are connected to form a mesh structure for transmitting a first power supply signal.

In an exemplary implementation mode, the display substrate at least includes a first conductive layer, a second conductive layer, and a third conductive layer that are disposed in sequence on a silicon base substrate along a direction perpendicular to the display apparatus, the silicon base substrate at least includes active layers of the first transistor to the fourth transistor, the first conductive layer at least includes gate electrodes of the first transistor to the fourth transistor, the second conductive layer includes at least the first electrode and the second electrode of the first transistor, and the third conductive layer includes at least the data signal line.

In an exemplary implementation mode, the display substrate further includes a fourth conductive layer, a fifth conductive layer, a sixth conductive layer, a seventh conductive layer, and an eighth conductive layer that are disposed on a side of the third conductive layer away from the silicon base substrate, the fourth conductive layer at least includes the first electrode plate of the first storage capacitor, the fifth conductive layer at least includes the second electrode plate of the first storage capacitor, the sixth conductive layer at least includes the third electrode plate of the second storage capacitor, the seventh conductive layer at least i includes the fourth electrode plate of the second storage capacitor, and the eighth conductive layer at least includes the first power supply line.

In an exemplary implementation mode, the first electrode plate of the first storage capacitor is connected to the active layer of the first transistor through at least one connection electrode, and the third electrode plate of the second storage capacitor is connected to the active layer of the second transistor through at least one connection electrode.

In an exemplary implementation mode, the third electrode plate of the second storage capacitor is connected to the second electrode plate of the first storage capacitor through a via.

In an exemplary implementation mode, the first power supply line is connected to the fourth electrode plate of the second storage capacitor through a via.

In another aspect, the present disclosure further provides a display apparatus, and the display apparatus includes the display substrate described above.

In yet another aspect, the present disclosure further provides a method of manufacturing a display substrate, the display substrate includes a plurality of sub-pixels forming a plurality of pixel rows and a plurality of pixel columns, at least one sub-pixel includes a pixel drive circuit, the method of manufacturing includes:
forming the pixel drive circuit in the at least one sub-pixel, wherein the pixel drive circuit includes at least a first transistor, a second transistor, a third transistor, and a fourth transistor, a first electrode of the first transistor is connected to a data signal line, a second electrode of the first transistor is connected to a gate electrode of the fourth transistor, a first electrode of the second transistor is connected to a first power supply line, a second electrode of the second transistor is connected to a first electrode of the fourth transistor, a first electrode of the third transistor is connected to a second power supply line, and a second electrode of the third transistor is connected to a second electrode of the fourth transistor, and wherein along a direction of a pixel row, the sub-pixel has a pixel width and there is an inter-electrode distance between the first electrode of the first transistor and the second electrode of the first transistor, the inter-electrode distance is greater than or equal to 0.5*the pixel width.

Other aspects of the present disclosure may be comprehended after drawings and detailed descriptions are read and understood.

### BRIEF DESCRIPTION OF DRAWINGS

Drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure. Shapes and sizes of various components in the drawings do not reflect actual scales, but are only intended to schematically illustrate contents of the present disclosure.

FIG. 1 is a schematic diagram of a structure of a silicon-based OLED display apparatus.

FIG. 2 is a schematic diagram of a planar structure of a silicon-based OLED display substrate.

FIG. 3 is a schematic diagram of a sectional structure of a silicon-based OLED display substrate.

FIG. 4 is an equivalent circuit diagram of a pixel drive circuit according to an exemplary embodiment of the present disclosure.

FIG. 5 is a schematic diagram of a planar structure of a display substrate according to an exemplary embodiment of the present disclosure.

FIG. 6 is a schematic diagram of a planar structure of another display substrate according to an exemplary embodiment of the present disclosure.

FIG. 7, FIG. 8 and FIG. 9 are schematic diagrams after a pattern of a first conductive layer is formed according to an embodiment of the present disclosure.

FIG. 10 is a schematic diagram after a pattern of a second insulation layer is formed according to an embodiment of the present disclosure.

FIG. 11 and FIG. 12 are schematic diagrams after a pattern of a second conductive layer is formed according to an embodiment of the present disclosure.

FIG. 13 is a schematic diagram after a pattern of a third insulation layer is formed according to an embodiment of the present disclosure.

FIG. 14 and FIG. 15 are schematic diagrams after a pattern of a third conductive layer is formed according to an embodiment of the present disclosure.

FIG. 16 is a schematic diagram after a pattern of a fourth insulation layer is formed according to an embodiment of the present disclosure.

FIG. 17 and FIG. 18 are schematic diagrams after a pattern of a fourth conductive layer is formed according to an embodiment of the present disclosure.

FIG. 19 and FIG. 20 are schematic diagrams after a pattern of a fifth conductive layer is formed according to an embodiment of the present disclosure.

FIG. 21 is a schematic diagram after a pattern of a sixth insulation layer is formed according to an embodiment of the present disclosure.

FIG. 22 and FIG. 23 are schematic diagrams after a pattern of a sixth conductive layer is formed according to an embodiment of the present disclosure.

FIG. 24 and FIG. 25 are schematic diagrams after a pattern of a seventh conductive layer is formed according to an embodiment of the present disclosure.

FIG. 26 is a schematic diagram after a pattern of an eighth insulation layer is formed according to an embodiment of the present disclosure.

FIG. 27 and FIG. 28 are schematic diagrams after a pattern of an eighth conductive layer is formed according to an embodiment of the present disclosure.

FIG. 29 is a schematic diagram of structures of a first storage capacitor and a second storage capacitor according to an embodiment of the present disclosure.

Reference signs are described as follows:

| | | |
|---|---|---|
| 1-first active layer; | 2-second active layer; | 3-third active layer; |
| 4-fourth active layer; | 11-first gate electrode; | 12-second gate |
| | | electrode; |
| 13-third gate electrode; | 14-fourth gate | 21-twenty-first |
| | electrode; | connection electrode; |
| 22-twenty-second | 23-twenty-third | 24-twenty-fourth |
| connection electrode; | connection electrode; | connection electrode; |
| 25-twenty-fifth | 27-first connection | 28-second power |
| connection electrode; | line; | supply line; |
| 31-thirty-first | 32-thirty-second | 33-thirty-third |
| connection electrode; | connection electrode; | connection electrode; |
| 34-thirty-fourth | 37-data signal line; | 41-forty-first |
| connection electrode; | | connection electrode; |
| 42-forty-second | 43-second connection | 51-fifty-first |
| connection electrode; | line; | connection electrode; |
| 52-fifty-second | 53-third connection | 61-first power supply |
| connection electrode; | line; | line; |
| 62-power supply | 63-anode connection | 71-data connection |
| connection line; | electrode; | electrode; |
| 72-inter-electrode | 81-first scan signal | 82-second scan signal |
| connection electrode; | line; | line; |
| 83-third scan signal | 91-first electrode | 92-second electrode |
| line; | plate; | plate; |
| 93-third electrode | 94-fourth electrode | 101-silicon base |
| plate; | plate; | substrate; |
| 102-drive circuit layer; | 103-light emitting | 104-first |
| | structure layer; | encapsulation layer; |
| 105-color film structure | 106-second | 107-cover plate |
| layer; | encapsulation layer; | layer; |

### DETAILED DESCRIPTION

To make objectives, technical solutions, and advantages of the present disclosure clearer, the embodiments of the present disclosure will be described in detail below with reference to the drawings. It is to be noted that implementation modes may be implemented in multiple different forms. Those of ordinary skills in the art can easily understand such a fact that modes and contents may be transformed into various forms without departing from the purpose and scope of the present disclosure. Therefore, the present disclosure should not be explained as being limited to the contents recorded in the following implementation modes only. The embodiments and features in the embodiments of the present disclosure can be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. Number of pixels in a display apparatus and number of sub-pixels in each pixel are not limited to the numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “middle”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the drawings, not to indicate or imply that involved apparatuses or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (i.e. drain electrode terminal, drain region, or drain) and the source electrode (i.e. source electrode terminal, source region, or source), and a current can flow through the drain electrode, the channel region, and the source electrode. It is to be noted that in the specification, the channel region refers to a region through which a current mainly flows.

In the present specification, in order to distinguish two electrodes of the transistor except the gate electrode, one of the two electrodes is directly referred to as a first electrode and the other is referred to as a second electrode. The first electrode may be a drain electrode and the second electrode may be a source electrode, or the first electrode may be a source electrode and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the present specification.

In the present specification, an “electrical connection” includes a case that constituent elements are connected together through an element with a certain electrical action. The “element with a certain electrical effect” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In the specification, “disposed in a same layer” adopted refers to a structure formed by patterning two (or more than two) structures through a same patterning process, and their materials may be the same or different. For example, materials of precursors for forming multiple structures disposed in a same layer are the same, and final materials may be the same or different.

A triangle, rectangle, trapezoid, pentagon, or hexagon, etc. in the present specification is not strictly defined, and it may be an approximate triangle, rectangle, trapezoid, pentagon, or hexagon, etc. There may be some small deformations caused by tolerance, and there may be a chamfer, an arc edge, deformation, etc.

In the present disclosure, “about” refers to that a boundary is defined not so strictly and numerical values within process and measurement error ranges are allowed.

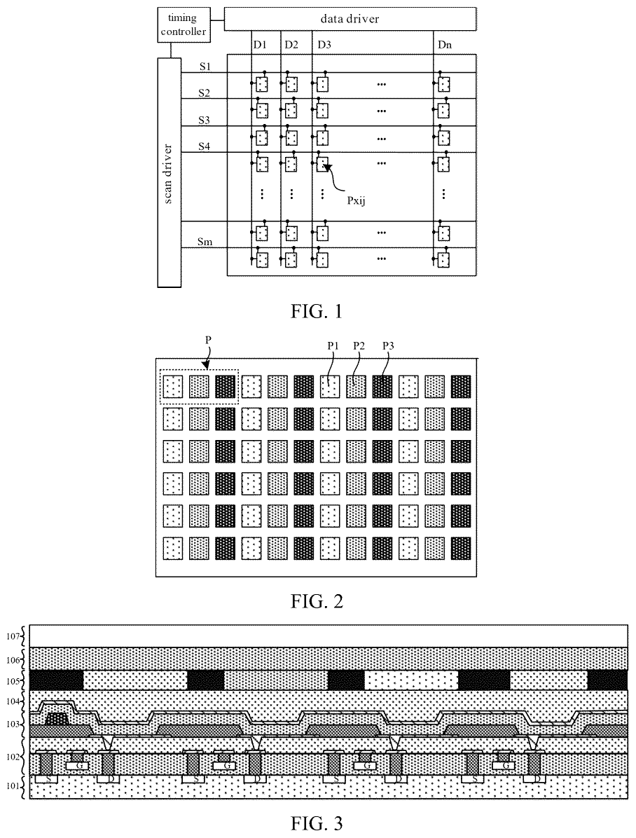

FIG. 1 is a schematic diagram of a structure of a silicon-based OLED display apparatus. As shown in FIG. 1, a silicon-based OLED display apparatus may include a timing controller, a data driver, a scan driver, and a pixel array. The timing controller is connected to the data driver and the scan driver respectively, the data driver is connected to a plurality of data signal lines (D1 to Dn) respectively, and the scan driver is connected to a plurality of scan signal lines (S1 to Sm) respectively. The pixel array may include a plurality of sub-pixels Pxij, where i and j may be natural numbers, and at least one sub-pixel Pxij may include a pixel drive circuit which is connected to a scan signal line and a data signal line respectively. In an exemplary implementation mode, the timing controller may provide a control signal and a gray scale value suitable for the specification of the data driver to the data driver, and may provide a scan start signal, a clock signal suitable for the specification of the scan driver and the like to the scan driver. The data driver may generate data voltages to be provided to the data signal lines D1, D2, D3, . . . , and Dn using the grayscale value and the control signal that are received from the timing controller. For example, the data driver may sample the gray scale value using the clock signal, and apply a data voltage corresponding to the gray scale value to the data signal lines D1 to Dn in a unit of a sub-pixel row, wherein n may be a natural number. The scan driver may generate a scan signals to be provided to the scan signal lines S1, S2, S3, . . . , and Sm by receiving the clock signal and the scan start signal and the like from the timing controller. For example, the scan driver may sequentially provide a scan signal with an on-level pulse to the scan signal lines S1 to Sm. For example, the scan driver may be constructed in a form of a shift register and generate a scan signal in a manner of sequentially transmitting scan start signals provided in a form of an on-level pulse to a next-stage circuit under control of the clock signal, wherein m may be a natural number. An array of sub-pixels may include the multiple sub-pixels Pxij. Each sub-pixel Pxij may be connected to a corresponding data signal line and a corresponding scan signal line, wherein i and j may be natural numbers. A sub-pixel Pxij may refer to a sub-pixel whose pixel drive circuit is connected to an i-th scan signal line and a j-th data signal line. In an exemplary implementation mode, the pixel array may be arranged on a display substrate.

FIG. 2 is a schematic diagram of a planar structure of a silicon-based OLED display substrate. As shown in FIG. 2, the display substrate may include a plurality of pixel units P arranged in a matrix, at least one of the plurality of pixel units P may include a first sub-pixel P1 emitting light of a first color, a second sub-pixel P2 emitting light of a second color, and a third sub-pixel P3 emitting light of a third color, each sub-pixel may include a pixel drive circuit and a light emitting device, a pixel drive circuit in a sub-pixel is connected to a scan signal line and a data signal line, respectively, and the pixel drive circuit is configured to receive a data voltage transmitted by the data signal line and output a corresponding current to a light emitting device under control of the scan signal line. The light emitting device in the sub-pixel is connected to the pixel drive circuit of the sub-pixel in which the light emitting device is located, and is configured to emit light with a corresponding brightness in response to a current output by the pixel drive circuit of the sub-pixel in which the light emitting device is located.

In an exemplary implementation mode, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation mode, the sub-pixels may be in a shape of any one or more of a triangle, a square, a rectangle, a rhombus, a trapezoid, a parallelogram, a pentagon, a hexagon, and other polygons. The three sub-pixels may be arranged in a manner to stand side by side horizontally, in a manner to stand side by side vertically, or in a manner of a shape of a Chinese character “ [symbol] ”, which is not limited here in the present disclosure. In other possible implementation modes, the pixel unit may include four sub-pixels, and the present disclosure is not limited thereto.

FIG. 3 is a schematic diagram of a sectional structure of a silicon-based OLED display substrate, illustrating a structure in which full color is implemented in a manner of white light+color film. As shown in FIG. 3, the silicon-based OLED display substrate may include a silicon base substrate 101, a drive circuit layer 102 disposed on the silicon base substrate 101, a light emitting structure layer 103 disposed on one side of the drive circuit layer 102 away from the silicon base substrate 101, a first encapsulation layer 104 disposed on one side of the light emitting structure layer 103 away from the silicon base substrate 101, a color film structure layer 105 disposed on one side of the first encapsulation layer 104 away from the silicon base substrate 101, a second encapsulation layer 106 disposed on one side of the color film structure layer 105 away from the silicon base substrate 101, and a cover plate layer 107 disposed on one side of the second encapsulation layer 106 away from the silicon base substrate 101. In some possible implementation modes, the silicon-based OLED display substrate may include other film layers, and the present disclosure is not limited thereto.

In an exemplary implementation mode, the silicon base substrate 101 may be a bulk silicon base substrate or a Silicon-On-Insulator (SOI) base substrate. The driving circuit layer 102 may be fabricated on the silicon base substrate 101 through a silicon semiconductor process (e.g., a CMOS process). The driving circuit layer 102 may include a plurality of circuit units, a circuit unit may at least include a pixel driving circuit connected to a scan signal line and a data signal line, respectively. The pixel driving circuit may include a plurality of transistors and a storage capacitor. One transistor is shown only in FIG. 3 as an example. A transistor is shown only in FIG. 3 as an example. The transistor may include a gate electrode G, a first electrode S, and a second electrode D. The gate electrode G, the first electrode S, and the second electrode D may be connected respectively to corresponding connection electrodes through vias filled with tungsten metal (i.e., tungsten vias (W-vias)), and may be connected to other electrical structures (e.g., wires) through the connection electrodes.

In an exemplary implementation mode, the light emitting structure layer 103 may include a plurality of light emitting devices, and a light emitting device may at least include an anode, an organic emitting layer, and a cathode. The anode may be connected to the second electrode D of the transistor through a connection electrode, the organic emitting layer is connected to the anode, the cathode is connected to the organic emitting layer, and the cathode is connected to a second power supply line. The organic emitting layer emits light under drive of the anode and the cathode. In an exemplary implementation mode, the organic emitting layer may include an Emitting Layer (EML) and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation mode, for a light emitting device emitting white light, organic emitting layers of all sub-pixels may be connected together to be a common layer.

In an exemplary implementation mode, the first encapsulation layer 104 and the second encapsulation layer 106 may be encapsulated in a manner of Thin Film Encapsulation (TFE), so as to ensure that external water vapor cannot enter the light emitting structure layer. The cover plate layer 107 may be made of glass, or plastic colorless polyimide having flexible characteristics, etc.

In an exemplary implementation mode, the color filter structure layer 105 may include a black matrix (BM) and color filters (CF). The color filters are provided in red (R) sub-pixels, green (G) sub-pixels and blue (B) sub-pixels respectively, and filter white light emitted by the light emitting devices into red (R) light, green (G) light and blue (B) light. The black matrix may be located between adjacent color filters.

At present, the silicon-based OLED display apparatus is gradually applied in the field of virtual reality (VR) or augmented reality (AR) near-eye display to enable users to experience real feelings in the virtual reality world, and has a super strong simulation system to implement human-computer interaction. Researches have shown that when resolution of a screen is high enough, the human retina cannot distinguish between pixels. Resolution (such as Pixels Per Inch, PPI for short) refers to number of pixels per unit area, which can be called pixel density. The higher the PPI value, the higher the density of the display substrate to display the picture, and the richer the details of the picture. Therefore, in order to improve the display quality, improving the PPI greatly has become the research emphasis of various manufacturers. However, researches have shown that the prior silicon-based OLED display apparatus have problems such as low anti-interference ability, which reduces the display quality.

An exemplary embodiment of the present disclosure provides a display substrate including a plurality of sub-pixels forming a plurality of pixel rows and a plurality of pixel columns, wherein at least one sub-pixel includes a pixel drive circuit including at least a first transistor, a second transistor, a third transistor, and a fourth transistor, a first electrode of the first transistor is connected to a data signal line, a second electrode of the first transistor is connected to a gate electrode of the fourth transistor, a first electrode of the second transistor is connected to a first power supply line, a second electrode of the second transistor is connected to a first electrode of the fourth transistor, a first electrode of the third transistor is connected to a second power supply line, a second electrode of the third transistor is connected to a second electrode of the fourth transistor, and wherein along a direction of pixel row, the at least one sub-pixel has a pixel width and there is an inter-electrode distance between the first electrode of the first transistor and the second electrode of the first transistor, and the inter-electrode distance is greater than or equal to 0.5*the pixel width.

In an exemplary implementation mode, the inter-electrode distance is greater than or equals to 0.85 μm.

In an exemplary implementation mode, along the direction of pixel row, there is a first distance between the first electrode of the first transistor and the data signal line, and there is a second distance between the second electrode of the first transistor and the data signal line, and the second distance is greater than the first distance.

In an exemplary implementation mode, the second distance is greater than or equals to 5*the first distance.

In an exemplary implementation mode, in the at least one sub-pixel, the first transistor at least includes a first active layer, the first active layer is in a shape of a strip extending along the direction of pixel row, the first active layer at least includes a first region and a second region, and the first region of the first active layer and the second region of the first active layer are arranged in sequence along the direction of pixel row.

In an exemplary implementation mode, the at least one sub-pixel further includes a data connection electrode and an inter-electrode connection electrode, a first end of the data connection electrode is connected to the first region of the first active layer through a first via, a second end of the data connection electrode is connected to the data signal line, a first end of the inter-electrode connection electrode is connected to the second region of the first active layer through a second via, and a second end of the inter-electrode connection electrode is connected to the gate electrode of the fourth transistor; the inter-electrode distance between the first electrode of the first transistor and the second electrode of the first transistor is a distance between a geometric center of the first via and a geometric center of the second via, the first distance between the first electrode of the first transistor and the data signal line is a distance between the geometric center of the first via and an edge of the data signal line on a side close to the first transistor, and the second distance between the second electrode of the first transistor and the data signal line is a distance between the geometric center of the second via and the edge of the data signal line on the side close to the first transistor.

The technical solutions of the display substrate in accordance with the present disclosure will be described below through exemplary embodiments.

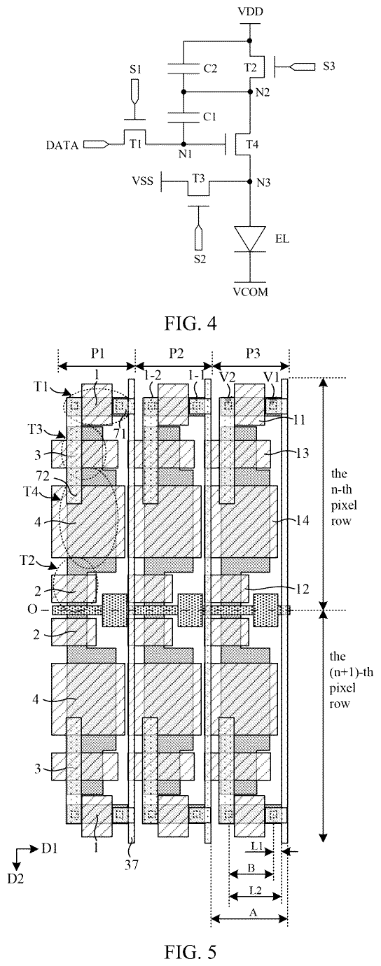

FIG. 4 is an equivalent circuit diagram of a pixel drive circuit according to an exemplary embodiment of the present disclosure. In an exemplary implementation mode, the pixel drive circuit may have a structure of 3T1C, 4T1C, 4T2C, 5T1C, 5T2C, 6T1C, or 7T1C etc. As shown in FIG. 4, in the exemplary embodiment of the present disclosure, the pixel drive circuit has a 4T2C structure and may include four transistors (e.g. a first transistor T1, a second transistor T2, a third transistor T3, and a fourth transistor T4) and two storage capacitors (a first storage capacitor C1 and a second storage capacitor C2). The pixel drive circuit is connected to six signal lines (e.g. a first scan signal line S1, a second scan signal line S2, a third scan signal line S3, a data signal line DATA, a first power supply line VDD, and a second power supply line VSS).

In an exemplary implementation mode, the pixel drive circuit may include a first node N1, a second node N2, and a third node N3. Here, the first node N1 is respectively connected to a second electrode of the first transistor T1, a gate electrode of the fourth transistor T4, and a first end of the first storage capacitor C1; a second electrode of the second transistor T2, a first electrode of the fourth transistor T4, a second end of the first storage capacitor C1, and a second end of the second storage capacitor C2 are connected; and the third node N3 is respectively connected to a second electrode of the third transistor T3 and a second electrode of the fourth transistor T4.

In an exemplary implementation mode, the first end of the first storage capacitor C1 is connected to the first node N1, the second end of the first storage capacitor C1 is connected to the second node N2, a first end of the second storage capacitor C2 is connected to the first power supply line VDD, and the second end of the second storage capacitor C2 is connected with the second node N2.

In an exemplary implementation mode, a gate electrode of the first transistor T1 is connected to the first scan signal line S1, a first electrode of the first transistor T1 is connected to the data signal line DATA, and the second electrode of the first transistor T1 is connected to the first node N1, and the first transistor T1 may be referred to as a data writing transistor.

In an exemplary implementation mode, a gate electrode of the second transistor T2 is connected to a third scan signal line S3, the first electrode of the second transistor T2 is connected to the first power supply line VDD, and the second electrode of the second transistor T2 is connected to the second node N2, and the second transistor T2 may be referred to as a light emitting control transistor.

In an exemplary implementation mode, a gate electrode of the third transistor T3 is connected to the second scan signal line S2, a first electrode of the third transistor T3 is connected to the second power supply line VSS, and the second electrode of the third transistor T3 is connected to the third node N3, and the third transistor T3 may be referred to as a reset transistor.

In an exemplary implementation mode, the gate electrode of the fourth transistor T4 is connected to the first node N1, the first electrode of the fourth transistor T4 is connected to the second node N2, and the second electrode of the fourth transistor T4 is connected to the third node N3, and the fourth transistor T4 may be referred to as a driving transistor.

In an exemplary implementation mode, the light emitting device EL may be an organic light emitting diode (OLED), including a first electrode (e.g. anode), an organic light emitting layer and a second electrode (e.g. cathode) that are stacked. A first electrode of the light emitting device EL is connected to the third node N3, and a second electrode of the light emitting device EL is connected to a common power supply line VCOM.

In an exemplary implementation mode, a signal of the first power supply line VDD may be a continuously provided high-level signal, and signals of the second power supply line VSS and the common power supply line VCOM may be continuously provided low-level signals.

In an exemplary implementation mode, the first transistor T1 to the fourth transistor T4 may be P-type transistors. In another exemplary implementation mode, the first transistor T1 to the fourth transistor T4 may be N-type transistors. Use of a same type of transistors in a pixel drive circuit may simplify a process flow, reduce a process difficulty of a display panel, and improve a product yield. In yet another exemplary implementation mode, the first transistor T1 to the fourth transistor T4 may include P-type transistors and N-type transistors. For example, the first transistor T1, the second transistor T2 and the third transistor T3 may be P-type metal oxide semiconductor transistors (PMOS), and the fourth transistor T4 may be an N-type metal oxide semiconductor transistor (NMOS).

In an exemplary implementation mode, a working process of the pixel drive circuit shown in FIG. 4 may include the first stage to the fourth stage.

1. A first stage (also referred to as an initialization stage). The first scan signal line S1, the second scan signal line S2, and the third scan signal line S3 output turn-on signals, and the first transistor T1, the second transistor T2, and the third transistor T3 are turned on. The first transistor T1 is turned on such that the data signal line DATA writes a voltage value Vofs to the first node N1, and the second transistor T2 is turned on such that the first power supply line VDD writes a voltage value Vdd to the second node N2, therefore a voltage difference Vgs between the first node N1 and the second node N2 equals to Vdd−Vofs. The third transistor T3 is turned on such that the second power supply line VSS writes a voltage value Vss to the third node N3 and initializes the third node N3 is to prevent a residual signal of a previous frame from affecting the display of a current frame.

2. A second stage H2 (a reading stage for a threshold voltage of self-discharge). The second scan signal line S2 outputs a turn-on signal, the first scan signal line S1 and the third scan signal line S3 output turn-off signals, the second transistor T2 is turned on, and the first transistor T1 and the third transistor T3 are turned off. Because the first node N1 is floating, and a voltage of the first node N1 changes with a voltage of the second node N2 under action of the first storage capacitor C1, therefore the voltage difference between the first node N1 and the second node N2 remains unchanged.

3. A third stage (a data writing and threshold compensation stage). The first scan signal line S1 and the second scan signal line S2 output turn-on signals, the third scan signal line S3 outputs a turn-off signal, the first transistor T1 and the third transistor T3 are turned on, and the second transistor T2 is turned off. The first transistor T1 causes the data signal line DATA to write a voltage value Vdata to the first node N1, and the voltage of the first node N1 changes from Vofs to Vdata. Because the second node N2 is floating, therefore the voltage of the second node N2 changes, with a changed value of voltage being related to a threshold voltage of the fourth transistor T4.

4. A fourth stage H4 (a light emitting stage). The third scan signal line S3 outputs a turn-on signal, the first scan signal line S1 and the second scan signal line S2 output turn-off signals, the second transistor T2 is turned on, the first transistor T1 and the third transistor T3 are turned off, and the fourth transistor T4 is turned on, a first power supply signal of the first power supply line VDD may supply a driving signal to the light-emitting device EL through the turned-on second transistor T2 and the turned-on fourth transistor T4 to drive the light-emitting device EL to emit light.

In a light-emitting stage of the light-emitting device EL, a current in a light-emitting path from the second node N2 to the third node N3 is independent of the threshold voltage of the fourth transistor T4.

FIG. 5 is a schematic diagram of a planar structure of a display substrate according to an exemplary embodiment of the present disclosure, schematically illustrating a structure of a pixel drive circuit of three sub-pixels in an n-th pixel row and an (n+1)-th pixel row. In an exemplary implementation mode, on a plane parallel to the display substrate, the display substrate may include a plurality of sub-pixels forming a plurality of pixel rows and a plurality of pixel columns, wherein a first sub-pixel P1, a second sub-pixel P2, and a third sub-pixel P3 in a pixel row are sequentially disposed along a first direction D1, the plurality of pixel rows are sequentially disposed along a second direction D2, the plurality of pixel rows and the plurality of pixel columns constitute a pixel array, and the first direction D1 and the second direction D2 intersect.

In an exemplary implementation mode, at least one sub-pixel may include a pixel drive circuit, and at least one pixel drive circuit may include at least a first transistor T1, a second transistor T2, a third transistor T3, and a fourth transistor T4. The first transistor T1 may include at least a first active layer 1 and a first gate electrode 11, the second transistor T2 may include at least a second active layer 2 and a second gate electrode 12, the third transistor T3 may include at least a third active layer 3 and a third gate electrode 13, and the fourth transistor T4 may include at least a fourth active layer 4 and a fourth gate electrode 14. In an exemplary implementation mode, a first electrode of the first transistor T1 is connected to a data signal line 37, a second electrode of the first transistor T1 is connected to the gate electrode 14 of the fourth transistor T4, a first electrode of the second transistor T2 is connected to a first power supply line (not shown), a second electrode of the second transistor T2 is connected to a first electrode of the fourth transistor T4, a first electrode of the third transistor T3 is connected to a second power supply line (not shown), and a second electrode of the third transistor T3 is connected to a second electrode of the fourth transistor T4.

In an exemplary implementation mode, the first active layer 1 may be a in a shape of a strip extending along the first direction D1, and the second active layer 2, the third active layer 3, and the fourth active layer 4 may be in a shape of a strip extending along the second direction D2. The first active layer 1 is provided separately, and the second active layer 2, the third active layer 3, and the fourth active layer 4 are connected to each other to form an integral structure to form a source-drain common structure of the second transistor T2 and the fourth transistor T4, and a source-drain common structure of the third transistor T3 and the fourth transistor T4. An orthographic projection of each gate electrode on the plane of the display substrate at least partially overlaps an orthographic projection of a corresponding active layer on the plane of the display substrate such that each active layer forms a channel region and a first region and a second region on both sides of the channel region.

In an exemplary implementation mode, a first region 1-1 of the first active layer and a second region 1-2 of the first active layer may be sequentially disposed along the first direction D1.

In an exemplary implementation mode, the at least one sub-pixel may further include a data connection electrode 71 and an inter-electrode connection electrode 72.

In an exemplary implementation mode, the data signal line 37 may be connected to the first region 1-1 of the first active layer through the data connection electrode 71 which may serve as the first electrode of the first transistor T1. In an exemplary implementation mode, a first end of the data connection electrode 71 is connected to the first region 1-1 of the first active layer through a first via V1, and a second end of the data connection electrode 71 is connected to the data signal line 37.

In an exemplary implementation mode, the gate electrode of the fourth transistor T4 may be connected to the second region 1-2 of the first active layer through the inter-electrode connection electrode 72 which may serve as the second electrode of the first transistor T1. In an exemplary implementation mode, a first end of the inter-electrode connection electrode 72 is connected to the second region 1-2 of the first active layer through a second via, and a second end of the inter-electrode connection electrode 72 is connected to the gate electrode of the fourth transistor T4.

In an exemplary implementation mode, in at least one sub-pixel, along the first direction D1 (a direction of the pixel row), the sub-pixel may have a pixel width A, and there may be an inter-electrode distance B between the data connection electrode 71 and the inter-electrode connection electrode 72, the inter-electrode distance B may be greater than or equal to 0.5*the pixel width A. In an exemplary implementation mode, the inter-electrode distance B may be a distance between a geometric center of the first via V1 and a geometric center of the second via V2.

In an exemplary implementation mode, the inter-electrode distance B may be greater than or equal to 0.85 μm.

In an exemplary implementation mode, in the at least one sub-pixel, there may be a first distance L1 between the data connection electrode 71 and the data signal line 37, and there may be a second distance L2 between the inter-electrode connection electrode 72 and the data signal line 37, with the second distance L2 being larger than the first distance L1. In an exemplary implementation mode, the first distance L1 may be a distance between the geometric center of the first via V1 and an edge of the data signal line 37 on a side close to the first transistor T1, and the second distance L2 may be a distance between the geometric center of the second via V2 and the edge of the data signal line 37 on the side close to the first transistor T1.

In an exemplary implementation mode, the second distance L2 may be greater than or equal to 5*the first distance L1.

In an exemplary implementation mode, the first transistor T1, the second transistor T2, the third transistor T3, and the fourth transistor T4 of two adjacent sub-pixels in at least one pixel column may be mirror-symmetrical with respect to a pixel center line, forming a structure in which the pixel drive circuit is horizontally inverted with respect to the pixel center line O. The pixel center line O is a straight line between two adjacent pixel rows and extending along the first direction D1.

In an exemplary implementation mode, the second active layers 12 of two adjacent sub-pixels in at least one pixel column may be connected to each other to form an integral structure, and to form a source common structure of the second transistors T2 of the adjacent sub-pixels in the pixel column.

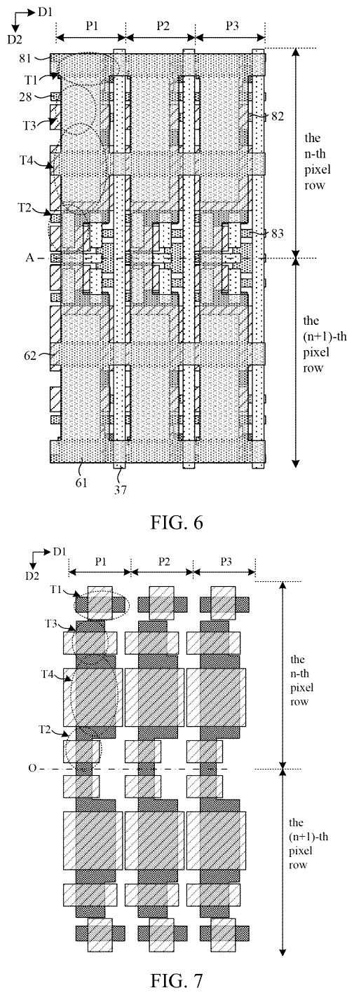

FIG. 6 is a schematic diagram of a planar structure of another display substrate according to an exemplary embodiment of the present disclosure, schematically illustrating a structure of a pixel drive circuit of three sub-pixels in the n-th pixel row and the (n+1)-th pixel row.

In an exemplary implementation mode, the at least one sub-pixel may further include a first scan signal line 81, a second scan signal line 82, a third scan signal line 83, a first power supply line 61, and a second power supply line 28, and the pixel drive circuit is connected to the first scan signal line 81, the second scan signal line 82, the third scan signal line 83, the data signal line 37, the first power supply line 61, and the second power supply line 28, respectively.

In an exemplary implementation mode, the first scan signal line 81, the second scan signal line 82, the third scan signal line 83, and the second power supply line 28 may be a in a shape of a line extending along the first direction D1, and are connected respectively to the pixel drive circuits of a plurality of sub-pixels in one pixel row. The data signal line 37 and the first power supply line 61 may be in a shape of a line extending along the second direction D2, and are connected respectively to the pixel drive circuits of a plurality of sub-pixels in one pixel column.

In an exemplary implementation mode, the gate electrode of the first transistor T1 is connected to the first scan signal line 81, the first electrode of the first transistor T1 is connected to the data signal line 37, and the second electrode of the first transistor T1 is connected to the gate electrode 14 of the fourth transistor T4. The gate electrode of the second transistor T2 is connected to the third scan signal line 83, the first electrode of the second transistor T2 is connected to the first power supply line 61, and the second electrode of the second transistor T2 is connected to the first electrode of the fourth transistor T4. The gate electrode of the third transistor T3 is connected to the second scan signal line 82, the first electrode of the third transistor T3 is connected to the second power supply line 28, and the second electrode of the third transistor T3 is connected to the second electrode of the fourth transistor T4.

In an exemplary implementation mode, in the at least one sub-pixel, an orthographic projection of the first power supply line 61 on the plane of the display substrate does not overlap with an orthographic projection of the data signal line 37 on the plane of the display substrate.

In an exemplary implementation mode, the at least one sub-pixel may further include at least one power supply connection line 62, the power supply connection line 62 may be in a shape of a line extending along the first direction D1, and the first power supply line 61 and the power supply connection line 62 are connected to form a mesh structure for transmitting a first power supply signal.

In an exemplary implementation mode, the first power supply line 61 and the power supply connection line 62 are arranged in a same layer and are connected to each other to form an integral structure.

In an exemplary implementation mode, in a direction perpendicular to the plane of the display apparatus, the display substrate may include a first conductive layer, a second conductive layer, and a third conductive layer that are sequentially disposed on a silicon base substrate, the silicon base substrate may include at least a first active layer 1, a second active layer 2, a third active layer 3, and a fourth active layer 4, the first conductive layer may include at least a first gate electrode 11, a second gate electrode 12, a third gate electrode 13, and a fourth gate electrode 14, the second conductive layer may include at least a first scan signal line 81, a second scan signal line 82, a third scan signal line 83, and a second power supply line 28, and the third conductive layer may include at least a data signal line 37.

In an exemplary implementation mode, in the at least one sub-pixel, the pixel drive circuit may further include a first storage capacitor and a second storage capacitor. The first storage capacitor may include a first electrode plate and a second electrode plate, an orthographic projection of the first electrode plate on the silicon base substrate at least partially overlaps with an orthographic projection of the second electrode plate on the silicon base substrate, the first electrode plate is connected to the gate electrode of the fourth transistor T4, and the second electrode plate is connected to the first electrode of the fourth transistor T4. The second storage capacitor includes a third electrode plate and a fourth electrode plate, an orthographic projection of the third electrode plate on the silicon base substrate at least partially overlaps with an orthographic projection of the fourth electrode plate on the silicon base substrate, the third electrode plate is connected to the first electrode of the fourth transistor T4, and the fourth electrode plate is connected to the first power supply line 61.

In an exemplary implementation mode, the display substrate may further include a fourth conductive layer, a fifth conductive layer, a sixth conductive layer, a seventh conductive layer, and an eighth conductive layer that are disposed on a side of the third conductive layer away from the silicon base substrate, the fourth conductive layer may include at least the first electrode plate of the first storage capacitor, the fifth conductive layer may include at least the second electrode plate of the first storage capacitor, the sixth conductive layer may include at least the third electrode plate of the second storage capacitor, the seventh conductive layer may include at least the fourth electrode plate of the second storage capacitor, and the eighth conductive layer may include at least the first power supply line 61 and the power supply connection line 62.

In an exemplary implementation mode, an orthographic projection of the data signal line 37 on the silicon base substrate does not overlap with an orthographic projection of the first electrode plate of the first storage capacitor on the silicon base substrate.

In an exemplary implementation mode, the orthographic projection of the data signal line 37 on the silicon base substrate does not overlap with an orthographic projection of the second electrode plate of the first storage capacitor on the silicon base substrate.

In an exemplary implementation mode, the orthographic projection of the data signal line 37 on the silicon base substrate does not overlap with an orthographic projection of the third electrode plate of the second storage capacitor on the silicon base substrate.

In an exemplary implementation mode, the orthographic projection of the data signal line 37 on the silicon base substrate does not overlap with an orthographic projection of the fourth electrode plate of the second storage capacitor on the silicon base substrate.

A manufacturing process of the display apparatus will be described below by way of example. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B being disposed in the same layer” mentioned in the present disclosure means that A and B are formed simultaneously through the same running of the patterning process, and a “thickness” of the film is a dimension of the film in a direction perpendicular to the display apparatus. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B.

In an exemplary implementation mode, taking three sub-pixels in an n-th pixel row and an (n+1)-th pixel row as examples, a manufacturing process of the display apparatus may include the following steps (1) to (13).

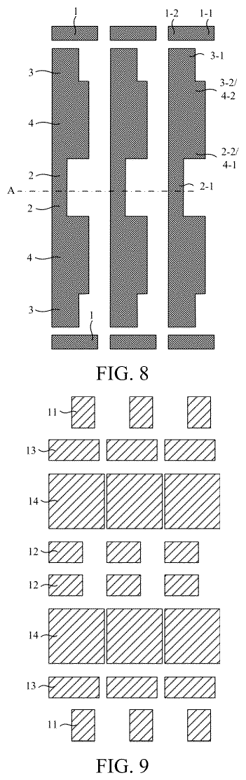

(1) Forming a pattern of a first conductive layer. In an exemplary implementation mode, forming the pattern of the first conductive layer may include: first providing a silicon base substrate of silicon material, then sequentially depositing a first insulation thin film and a polycrystalline silicon thin film on the silicon base substrate, patterning the first insulation thin film and the polycrystalline silicon thin film by a patterning process to form a first insulation layer and a pattern of a polycrystalline silicon layer provided on the first insulation layer, and doping the silicon base substrate by using the pattern of the polycrystalline silicon layer as a shield to form a pattern of an active layer and the pattern of the first conductive layer, as shown in FIGS. 7, 8 and 9, wherein FIG. 8 is a schematic diagram of the active layer in FIG. 7 and FIG. 9 is a schematic diagram of the first conductive layer in FIG. 7.

In an exemplary implementation mode, the silicon base substrate may employ P-type silicon material for a channel region of an N-type transistor, or the silicon base substrate may employ N-type silicon material for a channel region of a P-type transistor, and the present disclosure is not limited thereto.

In an exemplary implementation mode, a doping process may adopt an N-type doping process, and the doped element may be a boron element. The formed pattern of the active layer may at least include the first active layer 1 of the first transistor T1, the second active layer 2 of the second transistor T2, the third active layer 3 of the third transistor T3 and the fourth active layer 4 of the fourth transistor T4, and the formed pattern of the first conductive layer may at least include the first gate electrode 11 of the first transistor T1, the second gate electrode 12 of the second transistor T2, the third gate electrode 13 of the third transistor T3 and the fourth gate electrode 14 of the fourth transistor T4.

In an exemplary implementation mode, the doping process may adopt an ion implantation process. As the polycrystalline silicon layer is a semiconductor material, in the ion implantation process, on the one hand, the polycrystalline silicon layer may be used as a shield, so that ions are implanted into two sides of the polycrystalline silicon layer to form a first region and a second region of a plurality of transistors to realize self-alignment, on the other hand, the polycrystalline silicon layer may be doped at the same time, so that the polycrystalline silicon layer with higher resistance becomes the first conductive layer with lower resistance to form gate electrodes of a plurality of transistors. In the present disclosure, a polycrystalline silicon material is used as the first conductive layer, so that a process cost may be saved and a process difficulty may be reduced.

In an exemplary implementation mode, the first active layer 1 may be in a shape of a strip extending along the first direction D1, the second active layer 2 may be in a shape of a strip extending along the second direction D2, and the third active layer 3 and the fourth active layer 4 may be in a shape of a block, such as a rectangle, etc.

In an exemplary implementation mode, for a sub-pixel in the n-th pixel row, the third active layer 3 may be disposed on a side of the first active layer 1 in the second direction D2, the fourth active layer 4 may be disposed on a side of the third active layer 3 in the second direction D2, and the second active layer 2 may be disposed on a side of the fourth active layer 4 in the second direction D2. For a sub-pixel in the (n+1)-th pixel row, the fourth active layer 4 may be disposed on a side of the second active layer 2 in the second direction D2, the third active layer 3 may be disposed on a side of the fourth active layer 4 in the second direction D2, and the first active layer 1 may be disposed on a side of the third active layer 3 in the second direction D2.

In an exemplary implementation mode, the patterns of the active layers of sub-pixels in two adjacent pixel rows in the second direction D2 may be mirror-symmetric with respect to a pixel center line O, which is a straight line between the two adjacent pixel rows and extending along the first direction D1. For example, the first active layer 1 of the first sub-pixel P1 in the n-th pixel row and the first active layer 1 of the first sub-pixel P1 in the (n+1)-th pixel row may be mirror-symmetric with respect to the pixel center line O, the second active layer 2 of the first sub-pixel P1 in the n-th pixel row and the second active layer 2 of the first sub-pixel P1 in the (n+1)-th pixel row may be mirror-symmetric with respect to the pixel center line O, the third active layer 3 of the first sub-pixel P1 in the n-th pixel row and the third active layer 3 of the first sub-pixel P1 in the (n+1)-th pixel row may be mirror-symmetric with respect to the pixel center line O, and the fourth active layer 4 of the first sub-pixel P1 in the n-th pixel row and the fourth active layer 4 of the first sub-pixel P1 in the (n+1)-th pixel row may be mirror-symmetric with respect to the pixel center line O.

In an exemplary implementation mode, the patterns of the active layers of two adjacent sub-pixels in the first direction D1 may be substantially the same. For example, position and shape of the first active layer 1 of the first sub-pixel P1 may be substantially the same with position and shape of the first active layer 1 of the second sub-pixel P2, position and shape of the second active layer 2 of the first sub-pixel P1 may be substantially the same with position and shape of the second active layer 2 of the second sub-pixel P2, position and shape of the third active layer 3 of the first sub-pixel P1 may be substantially the same with position and shape of the third active layer 3 of the second sub-pixel P2, and position and shape of the fourth active layer 4 of the first sub-pixel P1 may be substantially the same with position and shape of the fourth active layer 4 of the second sub-pixel P2.

In an exemplary implementation mode, in the at least one sub-pixel, the second active layer 2 and the third active layer 3 may be connected to each other, and the third active layer 3 and the fourth active layer 4 may be connected to each other, that is, the second active layer 2, the third active layer 3, and the fourth active layer 4 may be connected to each other to form an integral structure, forming a source-drain common structure of the second transistor T2 and the fourth transistor T4, and a source-drain common structure of the third transistor T3 and the fourth transistor T4.

In an exemplary implementation mode, the second active layers 2 of the sub-pixels in two adjacent pixel rows in the second direction D2 may be connected to each other to form an integral structure, forming a source common structure of the second transistors T2 of adjacent sub-pixels in a pixel column. For example, the second active layer 2 of the first sub-pixel P1 in the n-th pixel row and the second active layer 2 of the first sub-pixel P1 in the (n+1)-th pixel row may be connected to each other to form an integral structure. As another example, the second active layer 2 of the second sub-pixel P2 in the n-th pixel row and the second active layer 2 of the second sub-pixel P2 in the (n+1)-th pixel row may be connected to each other to form an integral structure. As yet another example, the second active layer 2 of the third sub-pixel P3 in the n-th pixel row and the second active layer 2 of the third sub-pixel P3 in the (n+1)-th pixel row may be connected to each other to form an integral structure.

In an exemplary implementation mode, an orthographic projection of each gate electrode on a plane of the display substrate at least partially overlaps with an orthographic projection of a corresponding active layer on the plane of the display substrate, such that each active layer forms a channel region and a first region and a second region on both sides of the channel region. The first region 1-1 of the first active layer may be disposed on a side of the channel region of the first active layer in the first direction D1, and the second region 1-2 of the first active layer may be disposed on a side of the channel region of the first active layer in a direction opposite to the first direction D1. A first region 2-1 of the second active layer 2 may be disposed on a side of the channel region of the second active layer away from the fourth active layer 4, and a second region 2-2 of the second active layer 2 may be disposed on a side of the channel region of the second active layer close to the fourth active layer 4. A first region 3-1 of the third active layer 3 may be disposed on a side of the channel region of the third active layer 3 away from the fourth active layer 4, and a second region 3-2 of the third active layer 3 may be disposed on a side of the channel region of the third active layer 3 close to the fourth active layer 4. The second region 2-2 of the second active layer 2 may serve as a first region 4-1 of the fourth active layer, that is, the first region 4-1 of the fourth active layer and the second region 2-2 of the second active layer 2 are connected to each other. The second region 3-2 of the third active layer 3 may serve as a second region 4-2 of the fourth active layer, that is, the second region 4-2 of the fourth active layer and the second region 3-2 of the third active layer 3 are connected to each other. The first region 2-1 of the second active layer 2 in the n-th pixel row may serve as the first region 2-1 of the second active layer 2 in the (n+1)-th pixel row, that is, the first region 2-1 of the second active layer 2 in the n-th pixel row and the first region 2-1 of the second active layer 2 in the (n+1)-th pixel row are connected to each other.

By disposing the first active layer in a sub-pixel into a shape of a strip extending along the first direction D1 such that the first transistor T1 is laterally placed, the present disclosure not only can increase the distance between the first electrode of the first transistor T1 and the second electrode of the first transistor T1, minimize mutual influence between the first electrode and the second electrode to improve the anti-interference ability of the display apparatus, but also facilitates the first electrode of the first transistor T1 to be connected to the data signal line, facilitates the second electrode of the first transistor T1 to be connected to the gate electrode of the fourth transistor T4, and facilitates compressing an occupied area of the first transistor T1, decreasing a size of the pixel drive circuit and realizing a high resolution.

By disposing the second active layer 2, the third active layer 3, and the fourth active layer 4 in a sub-pixel as an integral structure connected to each other to form a source-drain common structure of the second transistor T2 and the fourth transistor T4, and a source-drain common structure of the third transistor T3 and the fourth transistor T4, the present disclosure can not only effectively reduce the area occupied by the pixel drive circuit, but also can simplify the structure, which is beneficial to realize high resolution.

By disposing the second active layers 2 in adjacent pixel rows as an integral structure connected to each other to form a source common structure of the second transistors T2 in the adjacent pixel rows, the present disclosure can not only effectively reduce an occupied area of the transistor, but also can reduce the number of vias, reduce the process difficulty, and improve the yield rate.

In an exemplary implementation mode, the first gate electrode 11 may be in a shape of a strip extending along the second direction D2, and a region in which the first gate electrode 11 overlaps with the first active layer 1 may serve as a channel region of the first active layer 1. The second gate electrode 12 may be in a shape of a strip extending along the first direction D1, and a region in which the second gate electrode 12 overlaps with the second active layer 2 may serve as a channel region of the second active layer 2. The third gate electrode 13 may be in a shape of a strip extending along the first direction D1, and a region in which the third gate electrode 13 overlaps with the third active layer 3 may serve as a channel region of the third active layer 3. The fourth gate electrode 14 may be in a shape of a rectangular, and a region in which the fourth gate electrode 14 overlaps with the fourth active layer 4 may serve as a channel region of the fourth active layer 4.

In an exemplary implementation mode, patterns of the first conductive layers of sub-pixels in two adjacent pixel rows in the second direction D2 may be mirror-symmetrical with respect to a pixel center line O. For example, the first gate electrode 11 of the first sub-pixel P1 in the n-th pixel row and the first gate electrode 11 of the first sub-pixel P1 in the (n+1)-th pixel row may be mirror-symmetric with respect to the pixel center line O, the second gate electrode 12 of the first sub-pixel P1 in the n-th pixel row and the second gate electrode 12 of the first sub-pixel P1 in the (n+1)-th pixel row may be mirror-symmetric with respect to the pixel center line O, the third gate electrode 13 of the first sub-pixel P1 in the n-th pixel row and the third gate electrode 13 of the first sub-pixel P1 in the (n+1)-th pixel row may be mirror-symmetric with respect to the pixel center line O, the fourth gate electrode 14 of the first sub-pixel P1 in the n-th pixel row and the fourth gate electrode 14 of the first sub-pixel P1 in the (n+1)-th pixel row may be mirror-symmetric with respect to the pixel center line O.

In an exemplary implementation mode, the patterns of the first conductive layers of two adjacent sub-pixels in the first direction D1 may be substantially the same. For example, position and shape of the first gate electrode 11 of the first sub-pixel P1 may be substantially the same with the position and shape of the first gate electrode 11 of the second sub-pixel P2, position and shape of the second gate electrode 12 of the first sub-pixel P1 may be substantially the same with the position and shape of the second gate electrode 12 of the second sub-pixel P2, position and shape of the third gate electrode 13 of the first sub-pixel P1 may be substantially the same with the position and shape of the third gate electrode 13 of the second sub-pixel P2, and position and shape of the fourth gate electrode 14 of the first sub-pixel P1 may be substantially the same with the position and shape of the fourth gate electrode 14 of the second sub-pixel P2.

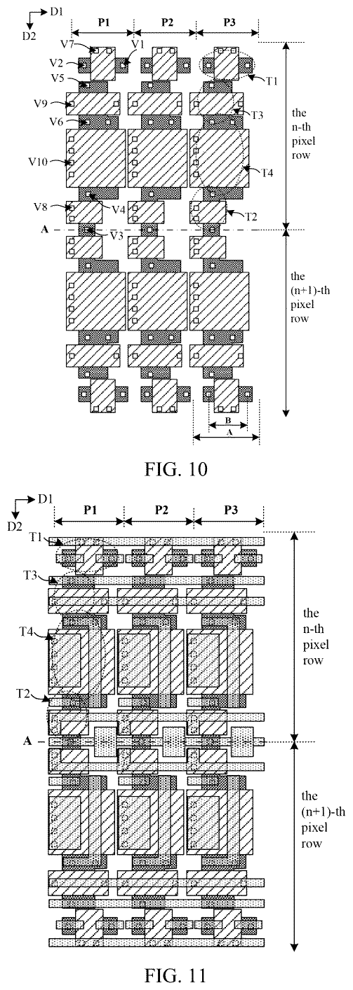

(2) Forming a pattern of a second insulation layer. In an exemplary implementation mode, forming the pattern of the second insulation layer may include: depositing a second insulation thin film on the silicon base substrate on which the aforementioned patterns are formed, and patterning the second insulation thin film through a patterning process to form the second insulation layer covering the pattern of the first conductive layer. A plurality of vias are disposed in the second insulation layer, as shown in FIG. 10.

In an exemplary implementation mode, the plurality of vias in each sub-pixel may at least include a first via V1, a second via V2, a third via V3, a fourth via V4, a fifth via V5, a sixth via V6, a seventh via V7, an eighth via V8, a ninth via V9 and a tenth via V10.

In an exemplary implementation mode, an orthographic projection of the first via V1 on the silicon base substrate may be located within a range of an orthographic projection of the first region of the first active layer on the silicon base substrate. The first insulation layer and the second insulation layer in the first via V1 are etched away to expose a surface of the first region of the first active layer, and the first via V1 is configured to connect a twenty first connection electrode formed subsequently to the first region of the first active layer through the first via V1.

In an exemplary implementation mode, an orthographic projection of the second via V2 on the silicon base substrate may be located within a range of an orthographic projection of the second region of the first active layer on the silicon base substrate. The first insulation layer and the second insulation layer in the second via V2 are etched away to expose a surface of the second region of the first active layer, and the second via V2 is configured to connect a twenty second connection electrode formed subsequently to the second region of the first active layer through the second via V2.

In an exemplary implementation mode, an orthographic projection of the third via V3 on the silicon base substrate may be located within a range of an orthographic projection of the first region of the second active layer on the silicon base substrate. The first insulation layer and the second insulation layer in the third via V3 are etched away to expose a surface of the first region of the second active layer, and the third via V3 is configured to connect a first connection line formed subsequently to the first region of the second active layer 2 through the third via V3.

In an exemplary implementation mode, an orthographic projection of the fourth via V4 on the silicon base substrate may be located within a range of an orthographic projection of the second region of the second active layer (also the first region of the fourth active layer) on the silicon base substrate. The first insulation layer and the second insulation layer in the fourth via V4 are etched away to expose a surface of the second region of the second active layer, and the fourth via V4 is configured to connect a twenty third connection electrode formed subsequently to the second region of the second active layer (also the first region of the fourth active layer) through the fourth via V4.

In an exemplary implementation mode, an orthographic projection of the fifth via V5 on the silicon base substrate may be located within a range of an orthographic projection of the first region of the third active layer 3 on the silicon base substrate. The first insulation layer and the second insulation layer in the fifth via V5 are etched away to expose a surface of the first region of the third active layer 3, and the fifth via V5 is configured to connect a second power supply line formed subsequently to the first region of the third active layer 3 through the fifth via V5.

In an exemplary implementation mode, an orthographic projection of the sixth via V6 on the silicon base substrate may be located within a range of an orthographic projection of the second region of the third active layer 3 (also the second region of the fourth active layer) on the silicon base substrate. The first insulation layer and the second insulation layer in the sixth via V6 are etched away to expose a surface of the second region of the third active layer 3, and the sixth via V6 is configured to connect a twenty fourth connection electrode formed subsequently to the second region of the third active layer 3 (also the second region of the fourth active layer) through the sixth via V6.

In an exemplary implementation mode, an orthographic projection of the seventh via V7 on the silicon base substrate may be located within a range of an orthographic projection of the first gate electrode 11 on the silicon base substrate. The second insulation layer in the seventh via V7 is etched away to expose a surface of the first gate electrode 11, and the seventh via V7 is configured to connect a first scan signal line formed subsequently to the first gate electrode 11 through the seventh via V7. In an exemplary implementation mode, there may be a plurality of seventh vias V7 to reduce contact resistance and improve connection reliability, and the plurality of seventh vias V7 may be located in an edge region of the first gate electrode 11 in a direction opposite to the second direction D2.

In an exemplary implementation mode, an orthographic projection of the eighth via V8 on the silicon base substrate may be located within a range of an orthographic projection of the second gate electrode 12 on the silicon base substrate. The second insulation layer in the eighth via V8 is etched away to expose a surface of the second gate electrode 12, and the eighth via V8 is configured to connect a third scan signal line formed subsequently to the second gate electrode 12 through the eighth via V8. In an exemplary implementation mode, there may be a plurality of eighth vias V8 to reduce contact resistance and improve connection reliability, and the plurality of eighth vias V8 may be located in an edge region of the second gate electrode 12 in a direction opposite to the first direction D1.

In an exemplary implementation mode, an orthographic projection of the ninth via V9 on the silicon base substrate may be located within a range of an orthographic projection of the third gate electrode 13 on the silicon base substrate. The second insulation layer in the ninth via V9 is etched away to expose a surface of the third gate electrode 13, and the ninth via V9 is configured to connect a second scan signal line formed subsequently to the third gate electrode 13 through the ninth via V9. In an exemplary implementation mode, there may be a plurality of ninth vias V9 to reduce contact resistance and improve connection reliability, and the plurality of ninth vias V9 may be respectively located in edge regions on both sides of the third gate electrode 13 in the first direction D1.

In an exemplary implementation mode, an orthographic projection of the tenth via V10 on the silicon base substrate may be located within a range of an orthographic projection of the fourth gate electrode 14 on the silicon base substrate. The second insulation layer in the tenth via V10 is etched away to expose a surface of the fourth gate electrode 14, and the tenth via V10 is configured to connect a twenty-fifth connection electrode formed subsequently to the fourth gate electrode 14 through the tenth via V10. In an exemplary implementation mode, there may be a plurality of tenth vias V10 to reduce contact resistance and improve connection reliability, and the plurality of tenth vias V10 may be located in an edge region of the fourth gate electrode 14 in a direction opposite to the first direction D1.

In an exemplary implementation mode, because the first via V1 is configured to connect a subsequently formed data connection electrode to the first region of the first active layer through the first via V1, and the first via V1 is a connection point enabling the connection between the first region of the first active layer and the data connection electrode, therefore the first via V1 may serve as a connection point between the first transistor T1 and an external circuit, i.e., a connection point of the first electrode of the first transistor T1.

In an exemplary implementation mode, because the second via V2 is configured to connect a subsequently formed inter-electrode connection electrode to the second region of the first active layer through the second via V2, and the second via V2 is a connection point enabling the connection between the second region of the first active layer and the inter-electrode connection electrode, therefore the second via V2 may serve as another connection point between the first transistor T1 and the external circuit, i.e., a connection point of the second electrode of the first transistor T1.

In an exemplary implementation mode, along the first direction D1, the first sub-pixel P1, the second sub-pixel P2, and the third sub-pixel P3 may each have a pixel width A, and there may be an inter-electrode distance B between a geometric center of the first via V1 and a geometric center of the second via V2, and the inter-electrode distance B may be greater than or equal to 0.5*the pixel width A.

In an exemplary implementation mode, the inter-electrode distance B is a distance between the connection point of the first electrode of the first transistor T1 and the connection point of the second electrode of the first transistor T1. By providing that the first active layer extends along the first direction D1 (i.e., the first transistor T1 is laterally placed), and the distance between the first electrode of the first transistor T1 and the second electrode of the first transistor T1 is greater than or equals to 0.5*the pixel width A, the present disclosure not only facilitates the connection between the first electrode of the first transistor T1 and the data signal line, but also effectively reduces mutual influence between the first electrode of the first transistor T1 and the second electrode of the first transistor T1, thus can ensure stability of a potential of the first node and improve the working performance of the pixel drive circuit.

In an exemplary implementation mode, the inter-electrode distance B may be greater than or equal to 0.85 μm based on a 0.11 μm manufacturing process.

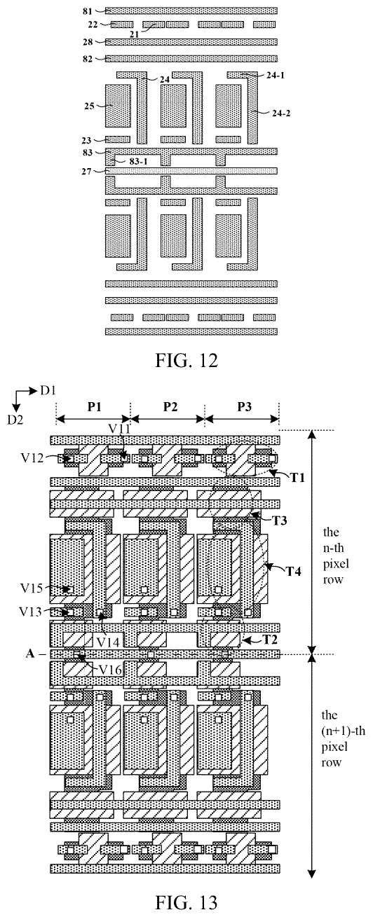

(3) Forming a pattern of a second conductive layer. In an exemplary implementation mode, forming the pattern of the second conductive layer may include: depositing a second conductive thin film on the silicon base substrate, on which the aforementioned patterns are formed, and patterning the second conductive film through a patterning process to form the pattern of the second conductive layer on the second insulation layer, as shown in FIGS. 11 and 12, wherein FIG. 12 is a schematic diagram of the second conductive layer in FIG. 11. In an exemplary implementation mode, the second conductive layer may be referred to as a first metal (Metal1) layer.

In an exemplary implementation mode, the pattern of the second conductive layer in each sub-pixel may at least include a twenty-first connection electrode 21, a twenty-second connection electrode 22, a twenty-third connection electrode 23, a twenty-fourth connection electrode 24, a twenty-fifth connection electrode 25, a first connection line 27, a second power supply line 28, a first scan signal line 81, a second scan signal line 82, and a third scan signal line 83.

In an exemplary implementation mode, the first scan signal line 81 may be in a shape of a line of which a main body portion extends along the first direction D1 and may be located on a side of the first active layer in a direction opposite to the second direction D2. The first scan signal line 81 may be connected to the first gate electrode 11 of each sub-pixel through the seventh via V7 of the sub-pixel and may provide a first scan signal to the first transistor T1 of each sub-pixel to control the first transistor T1 to be turned on or off.

In an exemplary implementation mode, the second scan signal line 82 may be in a shape of a line of which a main body portion extends along the first direction D1 and may be located between the first scan signal line 81 and the third scan signal line 83. The second scan signal line 82 may be connected to the third gate electrode 13 of each sub-pixel through the ninth via V9 of the sub-pixel and may provide a second scan signal to the third transistor T3 of each sub-pixel to control the third transistor T3 to be turned on or off.

In an exemplary implementation mode, the third scan signal line 83 may be in a shape of a line in which a main body portion extends along the first direction D1 and may be located on a side of the fourth active layer in the second direction D2. The third scan signal line 83 may be connected to the second gate electrode 12 of each sub-pixel through the eighth via V8 of the sub-pixel and may provide a second scan signal to the second transistor T2 of each sub-pixel to control the second transistor T2 to be turned on or off.

In an exemplary implementation mode, a third connection block 83-1 may be provided on the third scan signal line 83, wherein each sub-pixel may be provided with a third connection block 83-1, a first end of the third connection block 83-1 is connected to the third scan signal line 83, a second end of the third connection block 83-1 extending in a direction away from the third scan signal line 83, and the third connection block 83-1 is connected to the second gate electrode 12 through the eighth via V8.

In an exemplary implementation mode, the twenty-first connection electrode 21 may be in a shape of a strip extending along the first direction D1, and the twenty-first connection electrode 21 may be connected to the first region of the first active layer through the first via V1. The twenty-first connection electrode 21 may serve as a data connection electrode of the present disclosure (i.e., the first electrode of the first transistor T1), and the twenty-first connection electrode 21 is configured to be connected to a data signal line formed subsequently.

In an exemplary implementation mode, the twenty-second connection electrode 22 may be in a shape of a strip extending along the first direction D1, and the twenty-second connection electrode 22 may be connected to the second region of the first active layer through the second via V2. The twenty-second connection electrode 22 may serve as one sub-electrode of an inter-electrode connection electrode of the present disclosure (i.e., one sub-electrode of the second electrode of the first transistor T1), and the twenty-second connection electrode 22 is configured to be connected to a thirty-first connection electrode formed subsequently.

In an exemplary implementation mode, the twenty-third connection electrode 23 may be in a shape of a strip extending along the first direction D1, and the twenty-third connection electrode 23 may be connected to the second region of the second active layer (also the first region of the fourth active layer) through the fourth via V4. The twenty-third connection electrode 23 may serve as the second electrode of the second transistor T2 (also the first electrode of the fourth transistor T4), and is configured to be connected to the second electrode plate of the first storage capacitor and the third electrode plate of the second storage capacitor through a plurality of connection electrodes (including a thirty-second connection electrode) formed subsequently.

In an exemplary implementation mode, the twenty-fourth connection electrode 24 may be in a shape of an “L”, and may include a first sub-electrode 24-1 and a second sub-electrode 24-2. The first sub-electrode 24-1 may be in a shape of a strip extending along the first direction D1, and is connected to the second region of the third active layer 3 (also the second region of the fourth active layer) through the sixth via V6. The second sub-electrode 24-2 may be in a shape of a strip extending along the second direction D2, a first end of the second sub-electrode 24-2 is connected to the first sub-electrode 24-1, and a second end of the second sub-electrode 24-2 extends in a direction close to the third scan signal line 83. In an exemplary implementation mode, the twenty-fourth connection electrode 24 may serve as the second electrode of the third transistor T3 and the second electrode of the fourth transistor T4, and the twenty-fourth connection electrode 24 is configured to be connected to a thirty-third connection electrode formed subsequently.

In an exemplary implementation mode, the twenty-fifth connection electrode 25 may be in a shape of a rectangular, and the twenty-fifth connection electrode 25 may be connected to the fourth gate electrode 14 through the tenth via V10. The twenty-fifth connection electrode 25 may serve as the other sub-electrode in the inter-electrode connection electrode of the present disclosure and is configured to be connected to a thirty-first connection electrode formed subsequently.

In an exemplary implementation mode, the first connection line 27 may be in a shape of a line of which a main body portion extends along the first direction D1, and may be located between a third scan signal line 83 of the n-th pixel row and a third scan signal line 83 of the (n+1)-th pixel row. The first connection line 27 may be connected to the first region of the second active layer of each sub-pixel through the third via V3 of the sub-pixel. In an exemplary implementation mode, the first connection line 27 is configured to be connected to a first power supply line formed subsequently, thereby realizing that the first power supply line writes a first power supply signal to the first electrode of the second transistor T2 of each sub-pixel.

In an exemplary implementation mode, the second power supply line 28 may be in a shape of a line of which a main body portion extends along the first direction D1, and may be located between the first scan signal line 81 and the second scan signal line 82. The second power supply line 28 may be connected to the first region of the third active layer of each sub-pixel through the fifth via V5 of each sub-pixel, thereby realizing that the second power supply line 28 writes a second power supply signal to the first electrode of the third transistor T3 of each sub-pixel.

In an exemplary implementation mode, the patterns of the second conductive layers of sub-pixels in two adjacent pixel rows in the second direction D2 may be mirror symmetrical with respect to a pixel center line O. In an exemplary implementation mode, the patterns of the second conductive layers of two adjacent sub-pixels in the first direction D1 may be substantially the same.

(4) Forming a pattern of a third insulation layer. In an exemplary implementation mode, forming the pattern of the third insulation layer may include: depositing a third insulation thin film on the silicon base substrate, on which the aforementioned patterns are formed, and patterning the third insulation thin film through a patterning process to form the third insulation layer covering the pattern of the second conductive layer. A plurality of vias are disposed in the third insulation layer, as shown in FIG. 13.

In an exemplary implementation mode, the plurality of vias in each sub-pixel may include: an eleventh via V11, a twelfth via V12, a thirteenth via V13, a fourteenth via V14, a fifteenth via V15 and a sixteenth via V16.

In an exemplary implementation mode, an orthographic projection of the eleventh via V11 on the silicon base substrate may be located within a range of an orthographic projection of the twenty-first connection electrode 21 on the silicon base substrate. The third insulation layer in the eleventh via V11 is etched away to expose a surface of the twenty-first connection electrode 21, and the eleventh via V11 is configured to connect a data signal line formed subsequently to the twenty-first connection electrode 21 through the eleventh via V11.

In an exemplary implementation mode, an orthographic projection of the twelfth via V12 on the silicon base substrate may be located within a range of an orthographic projection of the twenty-second connection electrode 22 on the silicon base substrate. The third insulation layer in the twelfth via V12 is etched away to expose a surface of the twenty-second connection electrode 22, and the twelfth via V12 is configured to connect a thirty-first connection electrode formed subsequently to the twenty-second connection electrode 22 through the twelfth via V12.

In an exemplary implementation mode, an orthographic projection of a thirteenth via V13 on the silicon base substrate may be located within a range of an orthographic projection of the twenty-third connection electrode 23 on the silicon base substrate. The third insulation layer in the thirteenth via V13 is etched away to expose a surface of the twenty-third connection electrode 23, and the thirteenth via V13 is configured to connect a thirty-second connection electrode formed subsequently to the twenty-third connection electrode 23 through the thirteenth via V13.

In an exemplary implementation mode, an orthographic projection of the fourteenth via V14 on the silicon base substrate may be located within a range of an orthographic projection of the twenty-fourth connection electrode 24 on the silicon base substrate. The third insulation layer in the fourteenth via V14 is etched away to expose a surface of the twenty-fourth connection electrode 24, and the fourteenth via V14 is configured to connect a thirty-third connection electrode formed subsequently to the twenty-fourth connection electrode 24 through the fourteenth via V14. In an exemplary implementation mode, the fourteenth via V14 may be located in an end region of the second sub-electrode 24-2 in the second direction D2.

In an exemplary implementation mode, an orthographic projection of the fifteenth via V15 on the silicon base substrate may be located within a range of an orthographic projection of the twenty-fifth connection electrode 25 on the silicon base substrate. The third insulation layer in the fifteenth via V15 is etched away to expose a surface of the twenty-fifth connection electrode 25, and the fifteenth via V15 is configured to connect a thirty-first connection electrode formed subsequently to the twenty-fifth connection electrode 25 through the fifteenth via V15.

In an exemplary implementation mode, an orthographic projection of the sixteenth via V16 on the silicon base substrate may be located within a range of an orthographic projection of the first connection line 27 on the silicon base substrate. The third insulation layer in the sixteenth via V16 is etched away to expose a surface of the first connection line 27, and the sixteenth via V16 is configured to connect a thirty-fourth connection electrode formed subsequently to the first connection line 27 through the sixteenth via V16.

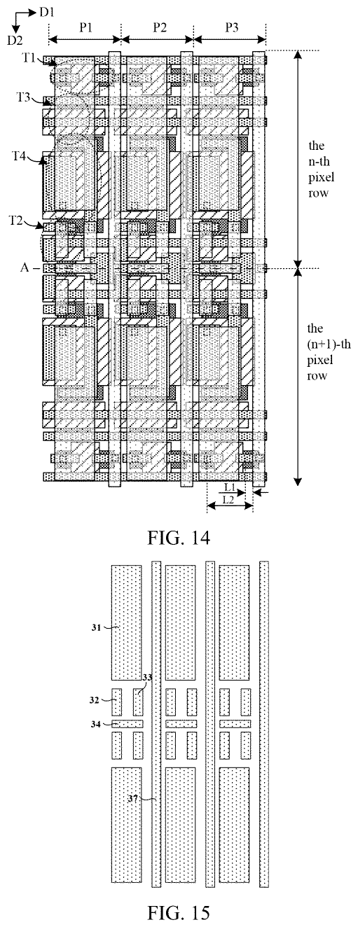

(5) Forming a pattern of a third conductive layer. In an exemplary implementation mode, forming the pattern of the third conductive layer may include: depositing a third conductive thin film on the silicon base substrate on which the aforementioned patterns are formed, and patterning the third conductive thin film through a patterning process to form the pattern of the third conductive layer on the third insulation layer, as shown in FIGS. 14 and 15, wherein FIG. 15 is a schematic diagram of the third conductive layer in FIG. 14. In an exemplary implementation mode, the third conductive layer may be referred to as a second metal (Metal2) layer.

In an exemplary implementation mode, the pattern of the third conductive layer in each sub-pixel may at least include a thirty-first connection electrode 31, a thirty-second connection electrode 32, a thirty-third connection electrode 33, a thirty-fourth connection electrode 34 and a data signal line 37.

In an exemplary implementation mode, the thirty-first connection electrode 31 may be in a shape of a strip extending along the second direction D2, an end of the thirty-first connection electrode 31 in a direction opposite to the second direction D2 may be connected to the twenty-second connection electrode 22 through the twelfth via V12, and an end of the thirty-first connection electrode 31 in the second direction D2 may be connected to the twenty-fifth connection electrode 25 through the fifteenth via V15. The twenty-second connection electrode 22 is connected to the second region of the first active layer, and the twenty-fifth connection electrode 25 is connected to the fourth gate electrode 14, thereby enabling the connection between the second electrode of the first transistor T1 and the gate electrode of the fourth transistor T4. In an exemplary implementation mode, the thirty-first connection electrode 31 is configured to be connected to a first electrode plate formed subsequently.

In an exemplary implementation mode, the thirty-first connection electrode 31 may serve as yet another sub-electrode in an inter-electrode connection electrode of the present disclosure (that is, yet another sub-electrode in the second electrode of the first transistor T1). The inter-electrode connection electrode may include a twenty-second connection electrode 22, a twenty-fifth connection electrode 25, and a thirty-first connection electrode 31, wherein the twenty-second connection electrode 22 is connected to the twenty-fifth connection electrode 25 through the thirty-first connection electrode 31, the twenty-second connection electrode 22 is connected to the second region of the first active layer, and the twenty-fifth connection electrode 25 is connected to the fourth gate electrode, thereby enabling the connection between the second electrode of the first transistor T1 and the gate electrode of the fourth transistor T4.

In an exemplary implementation mode, the thirty-second connection electrode 32 may be in a shape of a strip extending along the second direction D2, and the thirty-second connection electrode 32 may be connected to the twenty-third connection electrode 23 through the thirteenth via V13. The thirty-second connection electrode 32 is configured to be connected to a forty-first connection electrode formed subsequently.

In an exemplary implementation mode, the thirty-third connection electrode 33 may be in a shape of a strip extending along the second direction D2, and the thirty-third connection electrode 33 may be connected to the twenty-fourth connection electrode 24 through the fourteenth via V14. The thirty-third connection electrode 33 is configured to be connected to a forty-second connection electrode formed subsequently.

In an exemplary implementation mode, the thirty-fourth connection electrode 34 may be in a shape of a strip extending along the first direction D1, and may be located between the third scan signal line 83 of the n-th pixel row and the third scan signal line 83 of the (n+1)-th pixel row. The thirty-fourth connection electrode 34 may be connected to the first connection line 27 through the sixteenth via V16, and the thirty-fourth connection electrode 34 is configured to be connected to a second connection line formed subsequently.

In an exemplary implementation mode, the data signal line 37 may be in a shape of line extending along the second direction D2, and may be located on a side of a sub-pixel in the first direction D1. The data signal line 37 may be connected to the twenty-first connection electrode 21 of each sub-pixel through the eleventh via V11 of each sub-pixel. The twenty-first connection electrode 21 is connected to the first region of the first active layer, thereby enabling that the data signal line 37 writes a data signal to the first electrode of the first transistor T1 of each sub-pixel.

In an exemplary implementation mode, there may be a first distance L1 between an edge of the data signal line 37 on a side close to the first transistor T1 and the geometric center of the first via V1, and there may be a second distance L2 between the edge of the data signal line 37 on the side close to the first transistor T1 and the geometric center of the second via V2, and the second distance L2 may be greater than the first distance L1.

In an exemplary implementation mode, the second distance L2 may be greater than or equal to 5*the first distance L1.

In an exemplary implementation mode, the patterns of the third conductive layers of sub-pixels in two adjacent pixel rows in the second direction D2 may be mirror symmetrical with respect to a pixel centerline O. In an exemplary implementation mode, the patterns of the third conductive layers of two adjacent sub-pixels in the first direction D1 may be substantially the same.

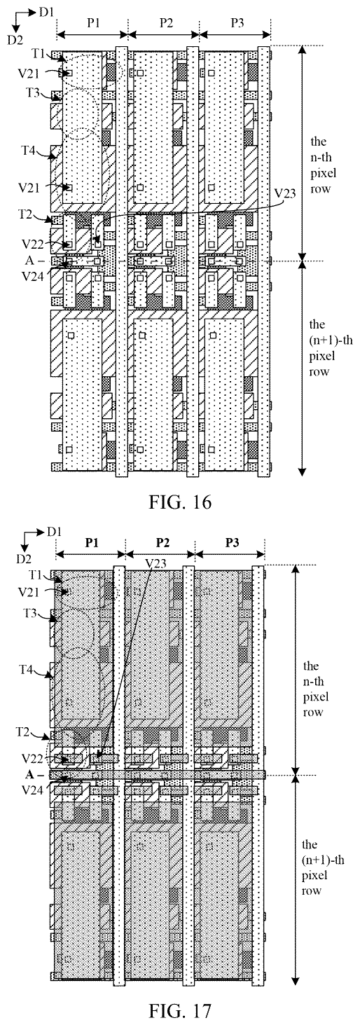

(6) Forming a pattern of a fourth insulation layer. In an exemplary implementation mode, forming the pattern of the fourth insulation layer may include: depositing a fourth insulation thin film on the silicon base substrate on which the aforementioned patterns are formed, and patterning the fourth insulation thin film through a patterning process to form the fourth insulation layer covering the pattern of the third conductive layer. A plurality of vias are disposed in the fourth insulation layer, as shown in FIG. 16.

In an exemplary implementation mode, the plurality of vias in each sub-pixel may include a twenty-first via V21, a twenty-second via V22, a twenty-third via V23, and a twenty-fourth via V24.

In an exemplary implementation mode, an orthographic projection of the twenty-first via V21 on the silicon base substrate may be located within a range of an orthographic projection of the thirty-first connection electrode 31 on the silicon base substrate. The fourth insulation layer in the twenty-first via V21 is etched away to expose a surface of the thirty-first connection electrode 31, and the twenty-first via V21 is configured to connect a first electrode plate formed subsequently to the thirty-first connection electrode 31 through the twenty-first via V21. In an exemplary embodiment, there may be a plurality of twenty-first vias V21 to reduce contact resistance and improve connection reliability, and the plurality of twenty-first vias V21 may be sequentially provided along the second direction D2.

In an exemplary implementation mode, an orthographic projection of the twenty-second via V22 on the silicon base substrate may be located within a range of an orthographic projection of the thirty-second connection electrode 32 on the silicon base substrate. The fourth insulation layer in the twenty-second via V22 is etched away to expose a surface of the thirty-second connection electrode 32, and the twenty-second via V22 is configured to connect a forty-first connection electrode formed subsequently to the thirty-second connection electrode 32 through the twenty-second via V22.

In an exemplary implementation mode, an orthographic projection of the twenty-third via V23 on the silicon base substrate may be located within a range of an orthographic projection of the thirty-third connection electrode 33 on the silicon base substrate. The fourth insulation layer in the twenty-third via V23 is etched away to expose a surface of the thirty-third connection electrode 33, and the twenty-third via V23 is configured to connect a forty-second connection electrode formed subsequently to the thirty-third connection electrode 33 through the twenty-third via V23.

In an exemplary implementation mode, an orthographic projection of the twenty-fourth via V24 on the silicon base substrate may be located within a range of an orthographic projection of the thirty-fourth connection electrode 34 on the silicon base substrate. The fourth insulation layer in the twenty-fourth via V24 is etched away to expose a surface of the thirty-fourth connection electrode 34, and the twenty-fourth via V24 is configured to connect a second connection line formed subsequently to the thirty-fourth connection electrode 34 through the twenty-fourth via V24. In an exemplary implementation mode, there may be a plurality of twenty-fourth vias V24 to reduce contact resistance and improve connection reliability, and the plurality of twenty-fourth vias V24 may be sequentially provided along the first direction D1.

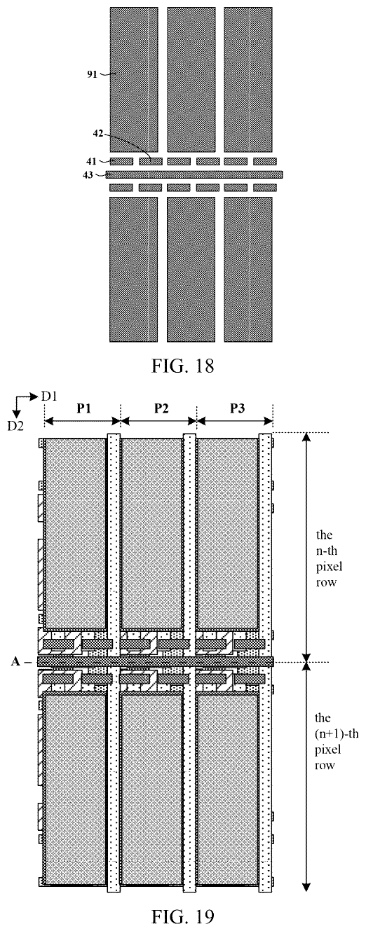

(7) Forming a pattern of a fourth conductive layer. In an exemplary implementation mode, forming the pattern of the fourth conductive layer may include: depositing a fourth conductive thin film on the silicon base substrate on which the aforementioned patterns are formed, and patterning the fourth conductive thin film through a patterning process to form the pattern of the fourth conductive layer on the fourth insulation layer, as shown in FIGS. 17 and 18, wherein FIG. 18 is a schematic diagram of the fourth conductive layer in FIG. 17. In an exemplary implementation mode, the fourth conductive layer may be referred to as a third metal (Metal3) layer.

In an exemplary implementation mode, the pattern of the fourth conductive layer of each sub-pixel may at least include a forty-first connection electrode 41, a forty-second connection electrode 42, a second connection line 43 and a first electrode plate 91.

In an exemplary implementation mode, the forty-first connection electrode 41 may be in a shape of a strip extending along the first direction D1, and the forty-first connection electrode 41 may be connected to the thirty-second connection electrode 32 through the twenty-second via V22. The forty-first connection electrode 41 is configured to be connected to a fifty-first connection electrode formed subsequently.

In an exemplary implementation mode, the forty-second connection electrode 42 may be in a shape of a strip extending along the first direction D1 and may be connected to the thirty-third connection electrode 33 through the twenty-third via V23. The forty-second connection electrode 42 is configured to be connected to a fifty-second connection electrode formed subsequently.

In an exemplary implementation mode, the second connection line 43 may be in a shape of a line extending along the first direction D1, and the second connection line 43 may be connected to the thirty-fourth connection electrodes 34 of a plurality of sub-pixels through the twenty-fourth vias V24 of the plurality of sub-pixels. A thirty-fourth connection electrode 34 in the third conductive layer is connected to the first connection line 27 in the second conductive layer through a via, such that the second connection line 43 in the fourth conductive layer and the first connection line 27 in the second conductive layer form a power supply connection line having a double-layer structure. In an exemplary implementation mode, the second connection line 43 is configured to be connected to a third connection line formed subsequently.

In an exemplary implementation mode, the first electrode plate 91 may be in a shape of a rectangle and may be connected to the thirty-first connection electrode 31 through a plurality of twenty-first vias V21. The first electrode plate 91 is configured to serve as a lower electrode plate of the first storage capacitor. Since the thirty-first connection electrode 31 is connected to the twenty-second connection electrode 22 and the twenty-fifth connection electrode 25 respectively through a via, the twenty-second connection electrode 22 is connected to the second region of the first active layer through a via, and the twenty-fifth connection electrode 25 is connected to the fourth gate electrode 14 through a via, therefore a connection between the first electrode plate 91, the second electrode of the first transistor T1 and the gate electrode of the fourth transistor T4 is enabled, and the first electrode plate 91, the second electrode of the first transistor T1 and the gate electrode of the fourth transistor T4 have a same potential to form the first node N1 of the pixel drive circuit, that is, the first electrode plate 91 has a potential of the first node N1.

In an exemplary implementation mode, an orthographic projection of the first electrode plate 91 on the silicon base substrate does not overlap with the orthographic projection of the data signal line 37 on the silicon base substrate.

In an exemplary implementation mode, the pixel drive circuit of the present disclosure is a current-type circuit, therefore a range of data voltage of the data signal line is small. By providing that the data signal line does not overlap with the first electrode plate, the present disclosure can reduce the parasitic capacitance between the data signal line and the first electrode plate, prevent a corresponding electrode in the pixel drive circuit from affecting the data voltage of the data signal line, improve the anti-interference ability of the data signal line, and improve the display quality to a greatest extent.

In an exemplary implementation mode, the patterns of the fourth conductive layers of sub-pixels in two adjacent pixel rows in the second direction D2 may be mirror symmetrical with respect to a pixel center line O. In an exemplary implementation mode, the patterns of the fourth conductive layers of two adjacent sub-pixels in the first direction D1 may be substantially the same.

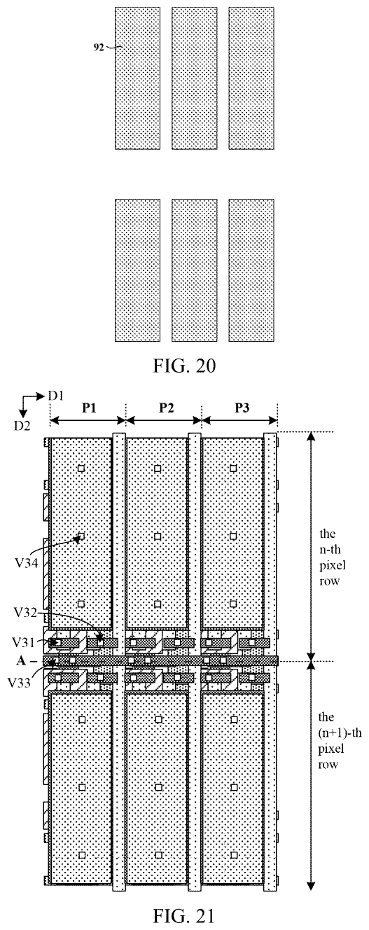

(8) Forming a fifth insulation layer and a pattern of a fifth conductive layer. In an exemplary implementation mode, forming the fifth insulation layer and the pattern of the fifth conductive layer may include: depositing in sequence a fifth insulation thin film and a fifth conductive thin film on the silicon base substrate, on which the aforementioned patterns are formed, and patterning the fifth conductive thin film through a patterning process to form the fifth insulation layer covering the pattern of the fourth conductive layer and the pattern of the fifth conductive layer disposed on the fifth insulation layer, as shown in FIGS. 19 and 20, wherein FIG. 20 is a schematic diagram of the fifth conductive layer in FIG. 19. In an exemplary implementation mode, the fifth conductive layer may be referred to as a metal-insulator-metal (MIM) layer.

In an exemplary implementation mode, the pattern of the fifth conductive layer in each sub-pixel may include at least a second electrode plate 92.

In an exemplary implementation mode, the second electrode plate 92 may be in a shape of a rectangle. An orthographic projection of the second electrode plate 92 on the silicon base substrate at least partially overlaps with an orthographic projection of the first electrode plate 91 on the silicon base substrate. The second electrode plate 92 is configured to serve as an upper electrode plate of the first storage capacitor, and the first electrode plate 91 and the second electrode plate 92 constitute the first storage capacitor of the pixel drive circuit. By providing a first storage capacitor having a plate capacitor structure, the present disclosure not only can solve a problem of limited area of the capacitor, but also can superimpose parasitic capacitance generated between the stacked layers to the capacitor itself to reduce the influence of the parasitic capacitance, thus improves gain of the capacitance value of the capacitor, and effectively increases the capacity and uniformity of the first storage capacitor.

In an exemplary implementation mode, an orthographic projection of the second electrode plate 92 on the silicon base substrate does not overlap with the orthographic projection of the data signal line 37 on the silicon base substrate.

In an exemplary implementation mode, the pixel drive circuit of the present disclosure is a current-type circuit, therefore the range of data voltage of the data signal line is small. By providing that the data signal line does not overlap with the second electrode plate, the present disclosure can reduce the parasitic capacitance between the data signal line and the second electrode plate, can prevent a corresponding electrode in the pixel drive circuit from affecting data voltage of the data signal line, improves the anti-interference ability of the data signal line, and improves the display quality to the greatest extent.

In an exemplary implementation mode, the patterns of the fifth conductive layers of sub-pixels in two adjacent pixel rows in the second direction D2 may be mirror symmetrical with respect to a pixel center line O. In an exemplary implementation mode, the patterns of the fifth conductive layers of two adjacent sub-pixels in the first direction D1 may be substantially the same.

(9) Forming a pattern of a sixth insulation layer. In an exemplary implementation mode, forming the pattern of the sixth insulation layer may include: depositing a sixth insulation thin film on the silicon base substrate on which the aforementioned patterns are formed, and patterning the sixth insulation thin film through a patterning process to form the sixth insulation layer covering the pattern of the fifth conductive layer. A plurality of vias are disposed in the sixth insulation layer, as shown in FIG. 21.

In an exemplary implementation mode, the plurality of vias in each sub-pixel may include a thirty-first via V31, a thirty-second via V32, a thirty-third via V33, and a thirty-fourth via V34.

In an exemplary implementation mode, an orthographic projection of the thirty-first via V31 on the silicon base substrate may be located within a range of an orthographic projection of the forty-first connection electrode 41 on the silicon base substrate. The sixth insulation layer and the fifth insulation layer in the thirty-first via V31 are etched away to expose a surface of the forty-first connection electrode 41, and the thirty-first via V31 is configured to connect a fifty-first connection electrode formed subsequently to the forty-first connection electrode 41 through the thirty-first via V31.

In an exemplary implementation mode, an orthographic projection of the thirty-second via V32 on the silicon base substrate may be located within a range of an orthographic projection of the forty-second connection electrode 42 on the silicon base substrate. The sixth insulation layer and the fifth insulation layer in the thirty-second via V32 are etched away to expose a surface of the forty-second connection electrode 42, and the thirty-second via V32 is configured to connect a fifty-second connection electrode formed subsequently to the forty-second connection electrode 42 through the thirty-second via V32.

In an exemplary implementation mode, an orthographic projection of the thirty-third via V33 on the silicon base substrate may be located within a range of an orthographic projection of the second connection line 43 on the silicon base substrate. The sixth insulation layer and the fifth insulation layer in the thirty-third via V33 are etched away to expose a surface of the second connection line 43, and the thirty-third via V33 is configured to connect a third connection line formed subsequently to the second connection line 43 through the thirty-third via V33. In an exemplary implementation mode, there may be a plurality of thirty-third vias V33 to reduce contact resistance and improve connection reliability, and the plurality of thirty-third vias V33 may be sequentially provided along the first direction D1.

In an exemplary implementation mode, an orthographic projection of the thirty-fourth via V34 on the silicon base substrate may be located within a range of an orthographic projection of the second electrode plate 92 on the silicon base substrate. The sixth insulation layer in the thirty-fourth via V34 is etched away to expose a surface of the second electrode plate 92, and the thirty-fourth via V34 is configured to connect a third electrode plate formed subsequently to the second electrode plate 92 through the thirty-fourth via V34. In an exemplary implementation mode, there may be a plurality of thirty-fourth vias V34 to reduce contact resistance and improve connection reliability, and the plurality of thirty-fourth vias V34 may be sequentially provided along the second direction D2.

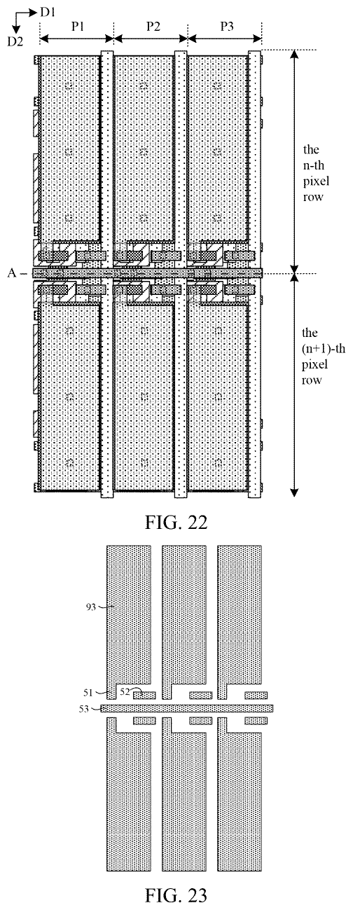

(10) Forming a pattern of a sixth conductive layer. In an exemplary implementation mode, forming the pattern of the sixth conductive layer may include: depositing a sixth conductive thin film on the silicon base substrate, on which the aforementioned patterns are formed, and patterning the sixth conductive film through a patterning process to form the pattern of the sixth conductive layer on the sixth insulation layer, as shown in FIGS. 22 and 23, wherein FIG. 23 is a schematic diagram of the sixth conductive layer in FIG. 22. In an exemplary implementation mode, the sixth conductive layer may be referred to as a fourth metal (Metal4) layer.

In an exemplary implementation mode, the pattern of the sixth conductive layer in each sub-pixel may at least include a fifty-first connection electrode 51, a fifty-second connection electrode 52, a third connection line 53, and a third electrode plate 93.

In an exemplary implementation mode, the third electrode plate 93 may be in a shape of a rectangular. An orthographic projection of the third electrode plate 93 on the silicon base substrate at least partially overlaps with an orthographic projection of the second electrode plate 92 on the silicon base substrate. The third electrode plate 93 is connected to the second electrode plate 92 through a plurality of thirty-fourth vias V34, and the third electrode plate 93 is configured to serve as a lower electrode plate of the second storage capacitor. Because the second electrode plate 92 and the third electrode plate 93 are connected, the second electrode plate 92 and the third electrode plate 93 have a same potential.

In an exemplary implementation mode, the orthographic projection of the third electrode plate 93 on the silicon base substrate does not overlap with an orthographic projection of the data signal line 37 on the silicon base substrate.

In an exemplary implementation mode, the pixel drive circuit of the present disclosure is a current-type circuit, therefore the range of data voltage of the data signal line is small. By providing that the data signal line does not overlap with the third electrode plate, the present disclosure can reduce the parasitic capacitance between the data signal line and the third electrode plate, can prevent a corresponding electrode in the pixel drive circuit from affecting data voltage of the data signal line, improves the anti-interference ability of the data signal line, and improves the display quality to a greatest extent.

In an exemplary implementation mode, the fifty-first connection electrode 51 may be in a shape of a block, wherein a first end of the fifty-first connection electrode 51 is connected to the third electrode plate 93, and a second end of the fifty-first connection electrode 51 is connected to the forty-first connection electrode 41 through the thirty-first via V31 after extending away from the third electrode plate 93 along the second direction D2. Since the forty-first connection electrode 41 is connected to the thirty-second connection electrode 32 through a via, the thirty-second connection electrode 32 is connected to the twenty-third connection electrode 23 through a via, and the twenty-third connection electrode 23 is connected to the second region of the second active layer (also the first region of the fourth active layer) through a via, therefore the connections of the second electrode plate 92 and the third electrode plate 93 to the second electrode of the second transistor T2 and the first electrode of the fourth transistor T4 are enabled, the second electrode plate 92, the third electrode plate 93, the second electrode of the second transistor T2 and the first electrode of the fourth transistor T4 have the same potential and form the second node N2 of the pixel drive circuit, that is, the second electrode plate 92 and the third electrode plate 93 have a potential of the second node N2.

In an exemplary implementation mode, the fifty-second connection electrode 52 may be in a shape of a strip extending along the first direction D1, and the fifty-second connection electrode 52 may be connected to the forty-second connection electrode 42 through the thirty-second via V32. The fifty-second connection electrode 52 is configured to be connected to an anode connection electrode formed subsequently.

In an exemplary implementation mode, the third connection line 53 may be in a shape of a line extending along the first direction D1, and the third connection line 53 may be connected to the second connection line 43 through the thirty-third via V33, so that the third connection line 53 in the sixth conductive layer, the second connection line 43 in the fourth conductive layer, and the first connection line 27 in the second conductive layer form a power supply connection line having a three-layer structure.

In an exemplary implementation mode, the patterns of the sixth conductive layers of sub-pixels in two adjacent pixel rows in the second direction D2 may be mirror symmetrical with respect to a pixel center line O. In an exemplary implementation mode, the patterns of the sixth conductive layers of two adjacent sub-pixels in the first direction D1 may be substantially the same.

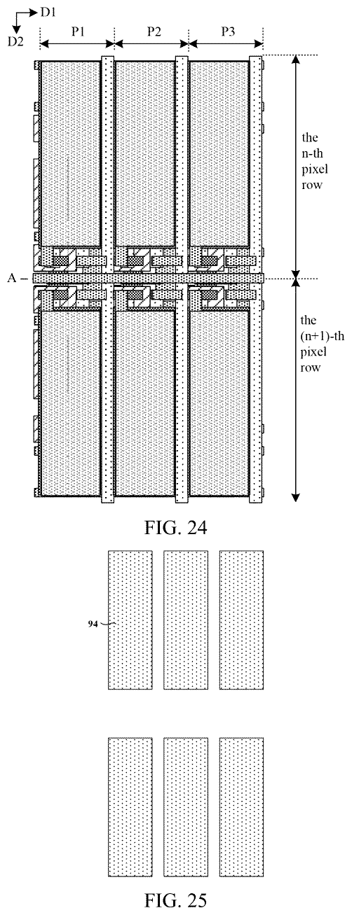

(11) Forming a seventh insulation layer and a pattern of a seventh conductive layer. In an exemplary implementation mode, forming the seventh insulation layer and the pattern of the seventh conductive layer may include: depositing in sequence a seventh insulation thin film and a seventh conductive thin film on the silicon base substrate, on which the aforementioned patterns are formed, and patterning the seventh conductive thin film through a patterning process to form a seventh insulation layer covering the pattern of the sixth conductive layer and the pattern of the seventh conductive layer disposed on the seventh insulation layer, as shown in FIGS. 24 and 25, wherein FIG. 25 is a schematic diagram of the seventh conductive layer in FIG. 24. In an exemplary implementation mode, the seventh conductive layer may be referred to as a top layer electrode plate (CTOP) layer.

In an exemplary implementation mode, the pattern of the seventh conductive layer in each sub-pixel may at least include a fourth electrode plate 94.

In an exemplary implementation mode, the fourth electrode plate 94 may be in a shape of a rectangle. An orthographic projection of the fourth electrode plate 94 on the silicon base substrate at least partially overlaps with the orthographic projection of the third electrode plate 93 on the silicon base substrate. The fourth electrode plate 94 is configured to serve as an upper electrode plate of the second storage capacitor, and the third electrode plate 93 and the fourth electrode plate 94 form the second storage capacitor of the pixel drive circuit. By providing a second storage capacitor having a plate capacitor structure, the present disclosure can not only solve a problem of limited area of the capacitor, but also can superimpose the parasitic capacitance generated between the stacked layers to the capacitor itself to reduce the influence of the parasitic capacitance, thus improves the gain of the capacitance value of the capacitor, and effectively increases the capacity and uniformity of the second storage capacitor.

In an exemplary implementation mode, an orthographic projection of the fourth electrode plate 94 on the silicon base substrate does not overlap with the orthographic projection of the data signal line 37 on the silicon base substrate.

In an exemplary implementation mode, the pixel drive circuit of the present disclosure is a current-type circuit, therefore the range of data voltage of the data signal line is small. By providing that the data signal line does not overlap with the fourth electrode plate, the present disclosure can reduce the parasitic capacitance between the data signal line and the fourth electrode plate, can prevent a corresponding electrode in the pixel drive circuit from affecting data voltage of the data signal line, thus improves the anti-interference ability of the data signal line, and improves the display quality to the greatest extent.

In an exemplary implementation mode, the patterns of the seventh conductive layers of sub-pixels in two adjacent pixel rows in the second direction D2 may be mirror symmetrical with respect to a pixel center line O. In an exemplary implementation mode, the patterns of the seventh conductive layers of two adjacent sub-pixels in the first direction D1 may be substantially the same.

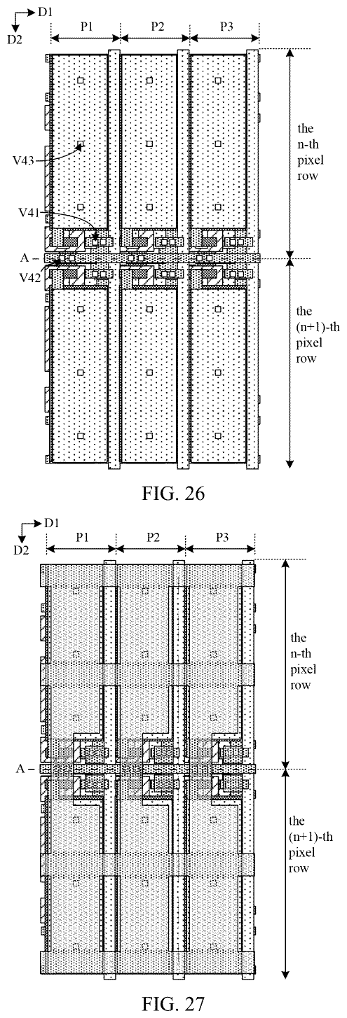

(12) Forming a pattern of an eighth insulation layer. In an exemplary implementation mode, forming the pattern of the eighth insulation layer may include: depositing an eighth insulation thin film on the silicon base substrate on which the aforementioned patterns are formed, and patterning the eighth insulation thin film through a patterning process to form the eighth insulation layer covering the pattern of the seventh conductive layer. A plurality of vias are disposed in the eighth insulation layer, as shown in FIG. 26.

In an exemplary implementation mode, the plurality of vias in each sub-pixel may include a forty-first via V41, a forty-second via V42 and a forty-third via V43.

In an exemplary implementation mode, an orthographic projection of the forty-first via V41 on the silicon base substrate is located within a range of an orthographic projection of the fifty-second connection electrode 52 on the silicon base substrate. The eighth insulation layer and the seventh insulation layer in the forty-first via V41 are etched away to expose a surface of the fifty-second connection electrode 52, and the forty-first via V41 is configured to connect an anode connection electrode formed subsequently to the fifty-second connection electrode 52 through the forty-first via V41.

In an exemplary implementation mode, an orthographic projection of the forty-second via V42 on the silicon base substrate is located within a range of an orthographic projection of the third connection line 53 on the silicon base substrate. The eighth insulation layer and the seventh insulation layer in the forty-second via V42 are etched away to expose a surface of the third connection line 53, and the forty-second via V42 is configured to connect a first power supply line formed subsequently to the third connection line 53 through the forty-second via V42.

In an exemplary implementation mode, an orthographic projection of the forty-third via V43 on the silicon base substrate is located within a range of an orthographic projection of the fourth electrode plate 94 on the silicon base substrate. The eighth insulation layer in the forty-third via V43 is etched away to expose a surface of the fourth electrode plate 94, and the forty-third via V43 is configured to connect a first power supply line formed subsequently to the fourth electrode plate 94 through the forty-third via V43. In an exemplary implementation mode, there may be a plurality of forty-third vias V43 to reduce contact resistance and improve connection reliability, and the plurality of forty-third vias V43 may be sequentially provided along the second direction D2.

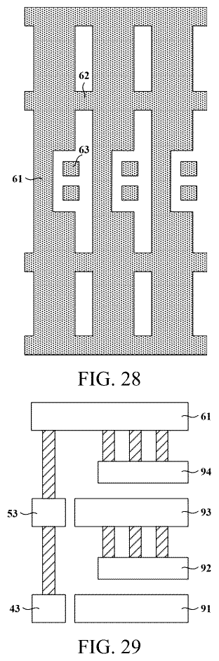

(13) Forming a pattern of an eighth conductive layer. In an exemplary implementation mode, forming the pattern of the eighth conductive layer may include: depositing an eighth conductive thin film on the silicon base substrate, on which the aforementioned patterns are formed, patterning the eighth conductive thin film through a patterning process to form the pattern of the eighth conductive layer disposed on the eighth insulation layer, as shown in FIGS. 27 and 28, wherein FIG. 28 is a schematic diagram of the eighth conductive layer in FIG. 27. In an exemplary implementation mode, the eighth conductive layer may be referred to as a fifth metal (Metal5) layer or a second metal connection (TM2) layer.

In an exemplary implementation mode, the eighth conductive layer in each sub-pixel may include at least a first power supply line 61, a power supply connection line 62, and an anode connection electrode 63.

In an exemplary implementation mode, the first power supply line 61 may be in a shape of a line extending along the second direction D2. On one hand, the first power supply line 61 is connected to the third connection line 53 through the forty-second via V42, and on the other hand, the first power supply line 61 is connected to the fourth electrode plate 94 through the forty-third via V43.

In an exemplary implementation mode, the fourth electrode plate 94 is connected to the first power supply line 61 through the forty-third via V43 and has a potential of the first power supply line 61, therefore the third electrode plate 93 having the potential of the second node N2 and the fourth electrode plate 94 having the potential of the first power supply line 61 form the second storage capacitor of the pixel drive circuit.

In an exemplary implementation mode, since the third connection line 53 is connected to the second connection line 43 through a via, the second connection line 43 is connected to the thirty-fourth connection electrode 34 through a via, the thirty-fourth connection electrode 34 is connected to the first connection line 27 through a via, and the first connection line 27 is connected to the first region of the second active layer through a via, the present disclosure not only realizes that the first power supply line can write a first power supply signal to the first electrode of the second transistor T2 of each sub-pixel, but also causes the third connection line 53 extending along the first direction D1 and the first power supply line 61 extending along the second direction D2 to form a mesh structure located in different layers on the display substrate for transmitting the first power supply signal. Therefore the present disclosure not only can effectively reduce resistance of the first power supply line and reduce a voltage drop of the first power supply signal, but also can effectively improve uniformity of the first power supply signal in the display substrate, effectively improve display uniformity, and improve display quality and display effect.

In an exemplary implementation mode, the power supply connection line 62 may be in a shape of a line extending along the first direction D1 and may be connected to the first power supply lines 61 of multiple sub-pixels, such that the power supply connection line 62 extending along the first direction D1 and the first power supply line 61 extending along the second direction D2 form a mesh structure located in a same layer on the display substrate for transmitting the first power supply signal, which not only can effectively reduce resistance of the first power supply line and reduce a voltage drop of the first power supply signal, but also can effectively improve uniformity of the first power supply signal in the display substrate, effectively improve display uniformity, and improve display quality.

In an exemplary implementation mode, the first power supply line 61 and the power supply connection line 62 may be connected to each other to form an integral structure.

In an exemplary implementation mode, the anode connection electrode 63 may be in a shape of a rectangle and may be connected to the fifty-second connection electrode 52 through the forty-first via V41. The anode connection electrode 63 is configured to be connected to an anode formed subsequently. Because the fifty-second connection electrode 52 is connected to the forty-second connection electrode 42 through a via, the forty-second connection electrode 42 is connected to the thirty-third connection electrode 33 through a via, the thirty-third connection electrode 33 is connected to the twenty-fourth connection electrode 24 through a via, and the twenty-fourth connection electrode 24 is connected to the second region of the third active layer and the second region of the fourth active layer through vias, therefore an anode formed subsequently can be enabled to be connected to the second electrode of the third transistor T3 and the second electrode of the fourth transistor T4 (i.e. the third node N3 of the pixel drive circuit), and the current outputted by the pixel drive circuit can be supplied to the anode.

In an exemplary implementation mode, the patterns of the eighth conductive layers of sub-pixels in two adjacent pixel rows in the second direction D2 may be mirror symmetrical with respect to the pixel center line O. In an exemplary implementation mode, the patterns of the eighth conductive layers of two adjacent sub-pixels in the first direction D1 may be substantially the same.

In an exemplary implementation mode, the subsequent manufacturing processes may include forming an anode, a pixel definition layer, an organic light emitting layer, a cathode, a first encapsulation layer, a color filter structure layer and a second encapsulation layer, the details thereof will not be repeated herein.

In an exemplary implementation mode, the first insulation film to the eighth insulation film may be made of silicon oxide (SiOx), silicon nitride (SiNx) or silicon oxynitride (SiON), or the like, and may be single-layer structures or multi-layer composite structures. The first metal layer to the fifth metal layer may be made of a metal material, such as Argentum (Ag), Copper (Cu), Aluminum (Al), or Molybdenum (Mo), or may be made of an alloy material formed by metals, such as Aluminum Neodymium (AlNd) alloy or Molybdenum Niobium (MoNb) alloy, and the alloy material may be a single-layer structure or may be a multi-layer composite structure, such as a composite structure formed by an Mo layer, a Cu layer, and an Mo layer. In an exemplary implementation mode, a plane shape of a via may be a rectangle, a circle, or an ellipse. Sizes of a plurality of vias may be the same or different, and the present disclosure is not limited thereto.

FIG. 29 is a schematic diagram of a structure of a first storage capacitor and a second storage capacitor in an exemplary embodiment of the present disclosure. As shown in FIG. 29, the first storage capacitor and the second storage capacitor are stacked, and the second storage capacitor is disposed on a side of the first storage capacitor away from the silicon base substrate.

In an exemplary implementation mode, the first storage capacitor may include a first electrode plate 91 and a second electrode plate 92 that are stacked, and the second storage capacitor may include a third electrode plate 93 and a fourth electrode plate 94 that are stacked. The first electrode plate 91 may be disposed in the fourth conductive layer (Metal3), the second electrode plate 92 may be disposed in the fifth conductive layer (MIM), the third electrode plate 93 may be disposed in the sixth conductive layer (Metal4), and the fourth electrode plate 94 may be disposed in the seventh conductive layer (CTOP). The third electrode plate 93 may be connected to the second electrode plate 92 through a via, and the fourth electrode plate 94 may be connected to the first power supply line 61 in the eighth conductive layer (Metal5) through a via.

In an exemplary implementation mode, the first electrode plate 91 may be connected to the second electrode of the first transistor T1 and the gate electrode of the fourth transistor T4 through a plurality of connection electrodes, respectively, so that the first electrode plate 91 has the potential of the first node N1. The third electrode plate 93 may be connected to the second electrode of the second transistor T2 and the first electrode of the fourth transistor T4 through a plurality of connection electrodes, respectively, so that the second electrode plate 92 and the third electrode plate 93 have the potential of the second node N2. Thus, the first electrode plate 91 having the potential of the first node N1 and the second electrode plate 92 having the potential of the second node N2 form the first storage capacitor of a pixel drive circuit, the third electrode plate 93 having the potential of the second node N2 and the fourth electrode plate 94 having the potential of the first power supply line form the second storage capacitor of the pixel drive circuit, and the first storage capacitor and the second storage capacitor having a stacked structure are formed.

In an exemplary implementation mode, the first power supply line 61 in the eighth conductive layer may be connected to the third connection line 53 in the sixth conductive layer through a via, the third connection line 53 in the sixth conductive layer may be connected to a second connection line 43 in the fourth conductive layer through a via, the second connection line 43 may be connected to the first connection line in the second conductive layer through at least one connection electrode, and the first connection line is connected to the first region of the second active layer through a via, thereby realizing that the first power supply line writes the first power supply signal to the first electrode of the second transistor T2 of each sub-pixel.

In an exemplary implementation mode, because the first storage capacitor and the second storage capacitor have a plate capacitor structure, only one insulation layer is provided between the first electrode plate 91 and the second electrode plate 92, and only one insulation layer is provided between the third electrode plate 93 and the fourth electrode plate 94, therefore capacities of the storage capacitors can be effectively guaranteed, and the arrangement of the pixel drive circuit can be made more compact on the premise of meeting the design requirements, which helps to improve the resolution of the display apparatus.

In an exemplary implementation mode, the capacities of the first storage capacitor and the second storage capacitor may be further increased by increasing the number of conductive layers.

In an exemplary implementation mode, since the first electrode plate 91 is connected to the second electrode of the first transistor T1 and the gate electrode of the fourth transistor T4 through connection electrodes or connection lines in the third conductive layer and the second conductive layer, therefore by increasing width of a connection electrode or connection line in the third conductive layer, the connection electrode or connection line may be enabled to serve as a sub-plate to form an auxiliary capacitor with a second electrode plate to increase the capacity of the first storage capacitor.

As can be seen from the structure and manufacturing process of the display substrate of an exemplary embodiment of the present disclosure, by setting a distance between the first electrode of the first transistor and the second electrode of the first transistor to be greater than or equal to 0.5*the pixel width, the present disclosure can effectively reduce mutual influence between the first electrode of the first transistor and the second electrode of the first transistor to ensure the stability of a potential of the key node in the pixel drive circuit, therefore improving the anti-interference ability of the display apparatus and improving the display quality.

By disposing the first active layer extending along the first direction D1, i.e., the first transistor is laterally disposed, the present disclosure not only facilitates the first electrode of the first transistor to be connected to the data signal line, facilitates the second electrode of the first transistor to be connected to the gate electrode of the fourth transistor, but also facilitates compressing the occupied area of the first transistor, facilitates reducing the size of the pixel drive circuit, and facilitates achieving higher resolution.

By providing that the second active layer, the third active layer, and the fourth active layer in a sub-pixel as an integral structure connected to each other, and providing that the second active layers 2 in adjacent pixel rows as an integral structure connected to each other, the present disclosure forms a source-drain common structure of the second transistor and the fourth transistor, a source-drain common structure of the third transistor and the fourth transistor, and a source common structure of the second transistors in the adjacent pixel rows, which can not only effectively reduce the occupied area of the pixel drive circuit, but can also simplify the structure, and is beneficial to realize high resolution.

By providing that the data signal line does not overlap with the electrode plates of the first storage capacitor and the second storage capacitor, the present disclosure can reduce the parasitic capacitance between the data signal line and the individual electrode plates, can prevent a corresponding electrode in the pixel drive circuit from affecting data voltage of the data signal line, improves the anti-interference ability of the data signal line, and improves the display quality to a greatest extent.

By adopting the first storage capacitor and the second storage capacitor having a plate capacitor structure, and stacking the first storage capacitor and the second storage capacitor, the present disclosure not only can solve the problem of limited area of the capacitor, but also can superimpose the parasitic capacitance generated by the stacked structure on the capacitor itself, which reduces the influence of the parasitic capacitance, and can be beneficial to gain the capacitance value of the capacitor, ensuring the stability and uniformity of the output current of the pixel drive circuit, and can make the arrangement of the pixel drive circuit more compact under the premise of meeting the design requirements, and is beneficial to improve the resolution of the display apparatus.

By providing the power supply connection line of which the main body portion extends along the first direction and the first power supply line of which the main body portion extends along the second direction, and connecting the first power supply line and the power supply connection line to each other such that the first power supply line and the power supply connection line form a mesh structure for transmitting a first power supply signal on the display substrate, the present disclosure not only can effectively reduce resistance of the first power supply line and reduce a voltage drop of the first power supply signal, but also can effectively improve uniformity of the first power supply signal in the display substrate, effectively improve display uniformity, and improve display quality and display effect.

By providing a relatively independent data signal line, which does not overlap with the first power supply line, and which has a small overlapping area with the power supply connection line, the present disclosure can minimize horizontal crosstalk, and improve display quality and display effect.

With the above structural design, the present disclosure optimizes the layout of the pixel drive circuit, optimizes the layout space, reduces the occupied area of the pixel drive circuit on the premise of improving the anti-interference ability, can realize a sub-pixel size of 1.69 μm×5.07 μm, can meet the Real RGB arrangement requirement, maximizes the resolution of the display substrate such that the resolution of the display substrate can be more than 5000, and can realize higher display quality and display effect.

Based on a 0.11 μm manufacturing process, the manufacturing process in the present disclosure may be compatible well with an existing manufacturing process, process implementation is simple and easy to implement, and has a high production efficiency, a low production cost and a high yield rate.

A structure of the display apparatus and the manufacturing process thereof according to exemplary embodiments of the present disclosure are described by way of example only. Corresponding structures may be changed and patterning processes may be added or reduced according to actual needs, the present disclosure is not limited thereto.

An exemplary embodiment of the present disclosure also provides a manufacturing method of a display substrate. In an exemplary implementation mode, the display substrate includes a plurality of sub-pixels forming a plurality of pixel rows and a plurality of pixel columns, and at least one sub-pixel includes a pixel drive circuit; the manufacturing method includes:
forming the pixel drive circuit in the at least one sub-pixel, wherein the pixel drive circuit includes at least a first transistor, a second transistor, a third transistor, and a fourth transistor, a first electrode of the first transistor is connected to a data signal line, a second electrode of the first transistor is connected to a gate electrode of the fourth transistor, a first electrode of the second transistor is connected to a first power supply line, a second electrode of the second transistor is connected to a first electrode of the fourth transistor, a first electrode of the third transistor is connected to a second power supply line, and a second electrode of the third transistor is connected to a second electrode of the fourth transistor, and wherein along the direction of a pixel row, the sub-pixel has a pixel width and there is an inter-electrode distance between the first electrode of the first transistor and the second electrode of the first transistor, the inter-electrode distance is greater than or equal to 0.5*the pixel width.

An exemplary embodiment of the present disclosure further provides a display apparatus, including the aforementioned display substrate. The display apparatus of the present disclosure may be used for a virtual reality device, an enhanced display device, or the like, and the display apparatus may also be used for any products or components having a display function, including, but not limited to, mobile phones, tablets, televisions, displays, notebook computers, digital photo frames, or navigators.

Although the implementation modes of the present disclosure are disclosed above, the above contents are only implementation modes for easily understanding the present disclosure and are not intended to limit the present disclosure. Any of those skilled in the art of the present disclosure can make any modifications and variations in the implementation mode and details without departing from the spirit and scope of the present disclosure. However, the protection scope of the present disclosure should be subject to the scope defined by the appended claims.

1. A display substrate comprising a plurality of sub-pixels forming a plurality of pixel rows and a plurality of pixel columns, wherein:
at least one sub-pixel comprises a pixel drive circuit at least comprising a first transistor, a second transistor, a third transistor, and a fourth transistor, a first electrode of the first transistor is connected to a data signal line, a second electrode of the first transistor is connected to a gate electrode of the fourth transistor, a first electrode of the second transistor is connected to a first power supply line, a second electrode of the second transistor is connected to a first electrode of the fourth transistor, a first electrode of the third transistor is connected to a second power supply line, a second electrode of the third transistor is connected to a second electrode of the fourth transistor; and
in the at least one sub-pixel, along a direction of a pixel row, the sub-pixel has a pixel width, and there is an inter-electrode distance between the first electrode of the first transistor and the second electrode of the first transistor, and the inter-electrode distance is greater than or equal to 0.5*the pixel width.

2. The display substrate according to claim 1, wherein the inter-electrode distance is greater than or equal to 0.85 μm.

3. The display substrate according to claim 1, wherein along the direction of the pixel row, there is a first distance between the first electrode of the first transistor and the data signal line, there is a second distance between the second electrode of the first transistor and the data signal line, and the second distance is greater than the first distance.

4. The display substrate according to claim 3, wherein the second distance is greater than or equal to 5*the first distance.

5. The display substrate according to claim 1, wherein in the at least one sub-pixel, the first transistor at least comprises a first active layer, the first active layer is in a shape of a strip extending along the direction of the pixel row, the first active layer at least comprises a first region and a second region, and the first region of the first active layer and the second region of the first active layer are arranged in sequence along the direction of the pixel row.

6. The display substrate according to claim 5, wherein the at least one sub-pixel further comprises a data connection electrode and an inter-electrode connection electrode;
a first end of the data connection electrode is connected to the first region of the first active layer through a first via; a second end of the data connection electrode is connected to the data signal line;
a first end of the inter-electrode connection electrode is connected to the second region of the first active layer through a second via, and a second end of the inter-electrode connection electrode is connected to the gate electrode of the fourth transistor; and
the inter-electrode distance between the first electrode of the first transistor and the second electrode of the first transistor is a distance between a geometric center of the first via and a geometric center of the second via, a first distance between the first electrode of the first transistor and the data signal line is a distance between the geometric center of the first via and an edge of the data signal line on a side close to the first transistor, and a second distance between the second electrode of the first transistor and the data signal line is a distance between the geometric center of the second via and the edge of the data signal line on the side close to the first transistor.

7. The display substrate according to claim 5, wherein in the at least one sub-pixel, the second transistor at least comprises a second active layer, the third transistor at least comprises a third active layer, and the fourth transistor at least comprises a fourth active layer; and the second active layer, the third active layer, and the fourth active layer are connected to each other to form an integral structure.

8. The display substrate according to claim 7, wherein in at least one pixel column, second active layers of two adjacent sub-pixels are connected to each other to form an integral structure.

9. The display substrate according to claim 1, wherein in at least one pixel column, pixel drive circuits of two adjacent sub-pixels are mirror-symmetrical with respect to a pixel centerline, and the pixel centerline is a straight line between two adjacent pixel rows and extending along the direction of the pixel row.

10. The display substrate according to claim 1, wherein, in the at least one sub-pixel, the pixel drive circuit further comprises a first storage capacitor and a second storage capacitor;
the first storage capacitor comprises a first electrode plate and a second electrode plate, an orthographic projection of the first electrode plate on a plane of the display substrate at least partially overlaps with an orthographic projection of the second electrode plate on the plane of the display substrate, the first electrode plate is connected to the gate electrode of the fourth transistor, and
the second electrode plate is connected to the first electrode of the fourth transistor; and the second storage capacitor comprises a third electrode plate and a fourth electrode plate, an orthographic projection of the third electrode plate on the plane of the display substrate at least partially overlaps with an orthographic projection of the fourth electrode plate on the plane of the display substrate, the third electrode plate is connected to the first electrode of the fourth transistor, and the fourth electrode plate is connected to the first power supply line.

11. The display substrate according to claim 10, wherein in the at least one sub-pixel, an orthographic projection of at least one of the first electrode plate, the second electrode plate, the third electrode plate, and the fourth electrode plate on the plane of the display substrate does not overlap with an orthographic projection of the data signal line on the plane of the display substrate.

12. The display substrate according to claim 1, wherein in the at least one sub-pixel, an orthographic projection of the first power supply line on a plane of the display substrate does not overlap with an orthographic projection of the data signal line on the plane of the display substrate.

13. The display substrate according to claim 1, wherein the at least one sub-pixel further comprises at least one power supply connection line, the power supply connection line is in a shape of a line extending along the direction of the pixel row, the first power supply line is in a shape of a line extending along a direction of a pixel column, and the first power supply line and the power supply connection line are connected to form a mesh structure for transmitting a first power supply signal.

14. The display substrate according to claim 1, wherein in a direction perpendicular to the display apparatus, the display substrate at least comprises a first conductive layer, a second conductive layer, and a third conductive layer that are disposed in sequence on a silicon base substrate, the silicon base substrate at least comprises active layers of the first transistor to the fourth transistor, the first conductive layer at least comprises gate electrodes of the first transistor to the fourth transistor, the second conductive layer at least comprises the first electrode and the second electrode of the first transistor, and the third conductive layer at least comprises the data signal line.

15. The display substrate according to claim 14, wherein the display substrate further comprises a fourth conductive layer, a fifth conductive layer, a sixth conductive layer, a seventh conductive layer, and an eighth conductive layer that are disposed on a side of the third conductive layer away from the silicon base substrate, the fourth conductive layer at least comprises a first electrode plate of a first storage capacitor, the fifth conductive layer at least comprises a second electrode plate of the first storage capacitor, the sixth conductive layer at least comprises a third electrode plate of a second storage capacitor, the seventh conductive layer at least comprises a fourth electrode plate of the second storage capacitor, and the eighth conductive layer at least comprises the first power supply line.

16. The display substrate according to claim 15, wherein the first electrode plate of the first storage capacitor is connected to the active layer of the first transistor through at least one connection electrode, and the third electrode plate of the second storage capacitor is connected to the active layer of the second transistor through at least one connection electrode.

17. The display substrate according to claim 15, wherein the third electrode plate of the second storage capacitor is connected to the second electrode plate of the first storage capacitor through a via.

18. The display substrate according to claim 15, wherein the first power supply line is connected to the fourth electrode plate of the second storage capacitor through a via.

19. A display apparatus, comprising the display substrate according to claim 1.

20. A manufacturing method for a display substrate, wherein the display substrate comprises a plurality of sub-pixels forming a plurality of pixel rows and a plurality of pixel columns, at least one sub-pixel comprises a pixel drive circuit, and the manufacturing method comprises:
forming the pixel drive circuit in the at least one sub-pixel, wherein:
the pixel drive circuit at least comprises a first transistor, a second transistor, a third transistor, and a fourth transistor, a first electrode of the first transistor is connected to a data signal line, a second electrode of the first transistor is connected to a gate electrode of the fourth transistor, a first electrode of the second transistor is connected to a first power supply line, a second electrode of the second transistor is connected to a first electrode of the fourth transistor, a first electrode of the third transistor is connected to a second power supply line, and a second electrode of the third transistor is connected to a second electrode of the fourth transistor; and
along a direction of a pixel row, the sub-pixel has a pixel width, there is an inter-electrode distance between the first electrode of the first transistor and the second electrode of the first transistor, and the inter-electrode distance is greater than or equal to 0.5*the pixel width.
